(19) United States
(12) Patent Application Publication
(10) Pub. No.: US 2026/0321213 A1
(43) Pub. Date: Oct. 15, 2026

(54) DISPLAY DEVICE AND ELECTRONIC DEVICE INCLUDING THE SAME

(71) Applicant: Samsung Display Co., LTD., Yongin-si (KR)

(72) Inventors: Soo Hong CHEON, Yongin-si (KR); Dong Hyun KIM, Yongin-si (KR)

(21) Appl. No.: 19/388,801

(22) Filed: Nov. 13, 2025

(30) Foreign Application Priority Data
Apr. 10, 2025 (KR) 10-2025-0046894

(51) Int. Cl. G09G 3/3266; G09G 3/32

(52) U.S. Cl. CPC G09G 3/3266; G09G 3/32; G09G 2300/0413; G09G 2300/0819; G09G 2310/0267

(57) ABSTRACT

A display device and an electronic device including the same are provided. The display device includes: a display area including subpixels; and a non-display area including a gate driving circuit configured to output a gate signal to the subpixels, and a plurality of dummy subpixels, wherein the dummy subpixels include a first dummy subpixel located between the gate driving circuit and a subpixel of the subpixels and a second dummy subpixel located between the first dummy subpixel and the subpixel, and the non-display area further includes a scan line group, an emission control line group, and a first constant voltage line group electrically connecting the first dummy subpixel and the second dummy subpixel and extending in a first direction and a second constant voltage line group located between the first dummy subpixel and the second dummy subpixel and extending in a second direction intersecting the first direction.

### CROSS-REFERENCE TO RELATED APPLICATION

This application claims priority to and the benefit of Korean Patent Application No. 10-2025-0046894, filed on Apr. 10, 2025, in the Korean Intellectual Property Office, the entire disclosure of which is incorporated by reference herein.

### BACKGROUND

### 1. Field

The present specification relates to a display device and an electronic device including the same.

### 2. Description of the Related Art

Electroluminescence displays can be divided into inorganic light emitting displays and organic light emitting displays depending on the material of a light emitting layer. An active matrix type organic light emitting display includes an organic light emitting diode (OLED) that emits light by itself and has fast response speed, high luminous efficiency, high luminance, and wide viewing angle. In the organic light emitting display, the OLED is formed in each pixel. The organic light emitting display not only has fast response speed and excellent luminous efficiency, luminance and viewing angle, but also has excellent contrast ratio and color gamut because it can express a black gray level as complete black.

### SUMMARY

Aspects and features of embodiments of the present disclosure are to improve the design stability of a display device.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes: a display area including a plurality of subpixels; and a non-display area including a gate driving circuit configured to output a gate signal to the subpixels, and a plurality of dummy subpixels, wherein the dummy subpixels include a first dummy subpixel located between the gate driving circuit and a subpixel of the subpixels and a second dummy subpixel located between the first dummy subpixel and the subpixel, and the non-display area further includes a scan line group, an emission control line group, and a first constant voltage line group electrically connecting the first dummy subpixel and the second dummy subpixel and extending in a first direction and a second constant voltage line group located between the first dummy subpixel and the second dummy subpixel and extending in a second direction intersecting the first direction.

In one or more embodiments, the first constant voltage line group is electrically connected to the second constant voltage line group through a plurality of contact holes.

In one or more embodiments, the subpixel includes a first transistor to applying a driving current to a light emitting element, a second transistor including a gate electrode to which a write scan signal is applied, a third transistor including a gate electrode to which a reset control signal is applied, and a fourth transistor including a gate electrode to which a bias scan signal is applied, and the scan line group includes a write scan line to supply the write scan signal, a reset control line to supply the reset control signal, and a bias scan line to supply the bias scan signal.

In one or more embodiments, the subpixel includes a first transistor to apply a driving current to a light emitting element, a fifth transistor including a gate electrode to which a first emission control signal is applied and a sixth transistor including a gate electrode to which a second emission control signal is applied, and the emission control line group includes a firs emission control line to supply the first emission control signal and a second emission control line to supply the second emission control signal.

In one or more embodiments, the subpixel includes a first transistor to apply a driving current to a light emitting element, a third transistor including an electrode to which a reference voltage is applied, a fifth transistor including an electrode to which a first driving voltage is applied and a fourth transistor including an electrode to which an initialization voltage is applied, and the first constant voltage line group includes a reference voltage line to supply the reference voltage, a first driving voltage line to supply the first driving voltage, and an initialization voltage line to supply the initialization voltage.

In one or more embodiments, the initialization voltage line includes a first initialization voltage line to supply a first initialization voltage, a second initialization voltage line to supply a second initialization voltage, and a third initialization voltage line to supplying a third initialization voltage, and the subpixels include a first subpixel to display a first color, a second subpixel to display a second color, and a third subpixel to display a third color, wherein the first initialization voltage is applied to the electrode of the fourth transistor in the first subpixel, the second initialization voltage is applied to the electrode of the fourth transistor in the second subpixel, and the third initialization voltage is applied to the electrode of the fourth transistor in the third subpixel.

In one or more embodiments, the second constant voltage line group includes: a reference voltage line to supply the reference voltage; a first driving voltage line to supply the first driving voltage; and an initialization voltage line to supply the initialization voltage.

In one or more embodiments, the initialization voltage line of the first constant voltage line group includes a first initialization voltage line to supply a first initialization voltage, a second initialization voltage line to supply a second initialization voltage, and a third initialization voltage line to supply a third initialization voltage, the initialization voltage line of the second constant voltage line group includes a first initialization voltage line to supply a first initialization voltage, a second initialization voltage line to supply a second initialization voltage and a third initialization voltage line to supply a third initialization voltage, and the subpixels include a first subpixel to display a first color, a second subpixel to display a second color, and a third subpixel to display a third color, wherein the first initialization voltage is applied to the electrode of the fourth transistor in the first subpixel, the second initialization voltage is applied to the electrode of the fourth transistor in the second subpixel, and the third initialization voltage is applied to the electrode of the fourth transistor in the third subpixel.

In one or more embodiments, the second constant voltage line group is located between a plurality of contact holes electrically connecting the first dummy subpixel and the first constant voltage line group and a plurality of contact holes electrically connecting the second dummy subpixel and the first constant voltage line group.

In one or more embodiments, the non-display area includes a bottom metal layer, a gate metal layer located on the bottom metal layer, and a connection metal layer located on the gate metal layer, a plurality of constant voltage lines in the first constant voltage line group are located in a same layer, and a plurality of constant voltage lines in the second constant voltage line group are located in a same layer.

In one or more embodiments, the non-display area includes a bottom metal layer, a gate metal layer located on the bottom metal layer, and a connection metal layer located on the gate metal layer, and the first constant voltage line group includes a constant voltage line located in a different layer from a constant voltage line in the second constant voltage line group.

In one or more embodiments, the first constant voltage line group includes a constant voltage line located on a constant voltage line in the second constant voltage line group.

In one or more embodiments, the first constant voltage line group is located on the second constant voltage line group.

In one or more embodiments, the reference voltage line of the second constant voltage line group includes a first sub-reference voltage line and a second sub-reference voltage line which supply the reference voltage.

In one or more embodiments, the reference voltage line of the first constant voltage line group is electrically connected to the first sub-reference voltage line and electrically connected to the second sub-reference voltage line.

In one or more embodiments, an electronic device includes: a processor configured to provide an image signal; a display module configured to receive the image signal from the processor and display an image; and a power module configured to supply power to the display module, wherein the display module includes: a display area including a plurality of subpixels; and a non-display area including a gate driving circuit configured to output a gate signal to the subpixels, and a plurality of dummy subpixels, wherein the dummy subpixels include a first dummy subpixel located between the gate driving circuit and a subpixel of the subpixels and a second dummy subpixel located between the first dummy subpixel and the subpixel, and the non-display area further includes a scan line group, an emission control line group, and a first constant voltage line group electrically connecting the first dummy subpixel and the second dummy subpixel and extending in a first direction and a second constant voltage line group located between the first dummy subpixel and the second dummy subpixel and extending in a second direction intersecting the first direction.

In one or more embodiments, the subpixel includes a first transistor to apply a driving current to a light emitting element, a third transistor including an electrode to which a reference voltage is applied, a fifth transistor including an electrode to which a first driving voltage is applied and a fourth transistor including an electrode to which an initialization voltage is applied, the first constant voltage line group includes a reference voltage line to supply the reference voltage, a first driving voltage line to supply the first driving voltage and an initialization voltage line to supply the initialization voltage, and the second constant voltage line group includes a reference voltage line to supply the reference voltage, a first driving voltage line to supply the first driving voltage, and an initialization voltage line to supply the initialization voltage.

In one or more embodiments, the second constant voltage line group is located between a plurality of contact holes electrically connecting the first dummy subpixel and the first constant voltage line group and a plurality of contact holes electrically connecting the second dummy subpixel and the first constant voltage line group.

In one or more embodiments, the non-display area includes a bottom metal layer, a gate metal layer located on the bottom metal layer, and a connection metal layer located on the gate metal layer, a plurality of constant voltage lines in the first constant voltage line group are located in a same layer, and a plurality of constant voltage lines in the second constant voltage line group are located in a same layer.

In one or more embodiments, the non-display area includes a bottom metal layer, a gate metal layer located on the bottom metal layer, and a connection metal layer located on the gate metal layer, and the first constant voltage line group includes a constant voltage line located in a different layer from a constant voltage line in the second constant voltage line group.

In a display device according to one or more embodiments of the present disclosure, a second constant voltage line group may be formed in a different layer from a first constant voltage line group. Accordingly, a line design area and a contact hole design area can be additionally secured.

Embodiments of the present disclosure supply a constant voltage to subpixels or dummy subpixels located in any one row through a plurality of contact holes. Therefore, the stability of a process of manufacturing a display device can be improved.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of an electronic device according to one or more embodiments of the present disclosure;

FIG. 2 is an exploded perspective view of the electronic device according to one or more embodiments of the present disclosure;

FIG. 3 is a plan view of a display device of FIG. 2;

FIG. 4 is a cross-sectional view taken along the line A-A’ of FIG. 3;

FIG. 5 is a plan view of a portion B of FIG. 3;

FIG. 6 is a block diagram of the display device of FIG. 2;

FIG. 7 is an equivalent circuit diagram of a subpixel circuit according to one or more embodiments of the present disclosure;

FIG. 8 is an equivalent circuit diagram of a dummy subpixel circuit according to one or more embodiments of the present disclosure;

FIGS. 9 and 10 are plan views of a display device according to one or more embodiments of the present disclosure;

FIG. 11 is a plan view of the display device according to one or more embodiments of the present disclosure;

FIG. 12 is a plan view of a display device according to one or more embodiments of the present disclosure;

FIG. 13 is a cross-sectional view of a display device according to one or more embodiments of the present disclosure;

FIGS. 14, 15, and 16 are cross-sectional views taken along the line I-I’ of FIG. 12;

FIG. 17 is a cross-sectional view taken along the line II-II’ of FIG. 12;

FIG. 18 is a plan view illustrating cut areas of FIGS. 19-23;

FIG. 19 is a cross-sectional view taken along the line III-III’ of FIG. 18;

FIG. 20 is a cross-sectional view taken along the line IV-IV’ of FIG. 18;

FIG. 21 is a cross-sectional view taken along the line V-V’ of FIG. 18;

FIG. 22 is a cross-sectional view taken along the line VI-VI’ of FIG. 18;

FIG. 23 is a cross-sectional view taken along the line VII-VII’ of FIG. 18;

FIG. 24 is a plan view of a first dummy subpixel according to one or more embodiments of the present disclosure;

FIG. 25 is a plan view of a first bottom metal layer according to one or more embodiments of the present disclosure;

FIG. 26 is a plan view of a second bottom metal layer according to one or more embodiments of the present disclosure;

FIG. 27 is a plan view of an active layer according to one or more embodiments of the present disclosure;

FIG. 28 is a plan view of a gate metal layer according to one or more embodiments of the present disclosure;

FIG. 29 is a plan view of a connection metal layer according to one or more embodiments of the present disclosure;

FIGS. 30 and 31 are plan views of the active layer and the gate metal layer according to one or more embodiments of the present disclosure;

FIG. 32 is a block diagram of an electronic device according to one or more embodiments of the present disclosure; and

FIG. 33 is a schematic diagram of electronic devices according to various embodiments of the present disclosure.

### DETAILED DESCRIPTION

The aspects and features of embodiments disclosed herein, and methods of achieving them, will become apparent upon reference to the embodiments described in detail with accompanying drawings. However, embodiments according to the present disclosure are not limited to embodiments disclosed herein, but will be embodied in many different forms, and these embodiments are provided merely to make the present disclosure complete and to fully inform one of ordinary skill in the art to which embodiments according to the present disclosure belongs, and embodiments according to the present disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are examples and are not intended to be limiting to those shown herein.

Although first, second, and/or the like are used to describe various components, the components are not limited by these terms. Thus, a first component referred to herein may also be a second component within the technical scope of the present disclosure.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Specific embodiments will be described below with reference to the accompanying drawings. Configurations that function substantially the same between embodiments are given the same drawing designation and repeated description is omitted.

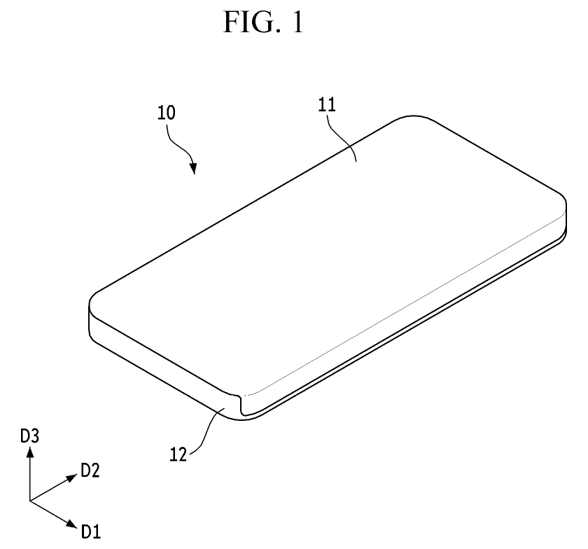

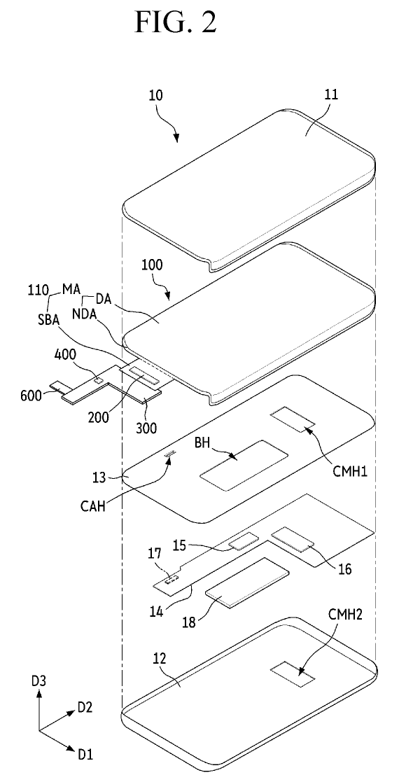

FIG. 1 is a perspective view of an electronic device 10 according to one or more embodiments of the present disclosure. FIG. 2 is an exploded perspective view of the electronic device 10 according to the embodiment of FIG. 1 of the present specification.

Referring to FIG. 1, the electronic device 10 according to one or more embodiments is a device having a function of displaying an image in a display area. The electronic device 10 may be portable. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device, and/or an ultra-mobile PC (UMPC).

However, the electronic device 10 according to the embodiment is not limited to a portable electronic device and may also be a large-sized device such as a television, a notebook computer, a monitor, a billboard, and/or an Internet of things (IOT) device.

The electronic device 10 according to the embodiment may include a cover window 11 and a bottom cover 12 provided as a housing to protect a display device.

Referring to FIG. 2, the electronic device 10 may further include a display device 100, a bracket 13, and a main circuit board 14 accommodated between the cover window 11 and the bottom cover 12.

The display device 100 may include a main area MA and a sub-area SBA protruding from a side of the main area MA. The main area MA may include a display area DA, in which image display is implemented, and a non-display area NDA around the display area DA along an edge or a periphery of the display area DA.

The display device 100 may further include a display driving circuit 200 located in the sub-area SBA, a display circuit board 300 bonded to a side of the sub-area SBA, a touch driving circuit 400 mounted on the display circuit board 300, and a cable 600 extending from a side of the display circuit board 300.

In the present specification, a first direction D1 may be a direction parallel to short sides of the electronic device 10 in a plan view, that is, a horizontal direction of the electronic device 10. A second direction D2 may be a direction parallel to long sides of the electronic device 10 in a plan view, that is, a vertical direction of the electronic device 10. A third direction D3 may be a thickness direction of the electronic device 10.

The electronic device 10 may have a shape close to a rectangle in a plan view. For example, the electronic device 10 may have a rectangular planar shape having short sides in the first direction D1 and long sides in the second direction D2. Each corner where a short side extending in the first direction D1 meets a long side extending in the second direction D2 may be rounded to have a selected curvature or may be right-angled. The planar shape of the electronic device 10 is not limited to a rectangular shape but may also be other polygonal shapes, a circular shape, or an oval shape.

The cover window 11 may be placed on the display device 100 to cover an upper surface of the display device 100. The cover window 11 may serve to protect the upper surface of the display device 100. The cover window 11 may include a light transmitting portion which is transparent and a light blocking portion which is opaque. The light transmitting portion may overlap the display area DA of the display device 100 in the third direction D3, and the light blocking portion may overlap the non-display area NDA of the display device 100 in the third direction D3.

The cover window 11 may include an upper surface portion that forms an upper surface of the electronic device 10, a left side surface portion that forms a left side surface of the electronic device 10, and a right side surface portion that forms a right side surface of the electronic device 10. The left side surface portion of the cover window 11 may extend from a left side of the upper surface portion, and the right side surface portion may extend from a right side of the upper surface portion.

Each of the upper surface portion, the left side surface portion, and the right side surface portion of the cover window 11 may include a light transmitting portion and a light blocking portion.

The light transmitting portion of the cover window 11 may be located in most of each of the upper surface portion, the left side surface portion, and the right side surface portion of the cover window 11.

The light blocking portion of the cover window 11 may be located at an upper edge and lower edge of the upper surface portion of the cover window 11, at an upper edge, left edge, and lower edge of the left side surface portion of the cover window 11, and at an upper edge, right edge, and lower edge of the right side surface portion of the cover window 11.

The display device 100 may be located under the cover window 11.

That is, the cover window 11 may be located on the display device 100.

The display device 100 may include an upper surface portion facing the upper surface portion of the cover window 11, a left side surface portion facing the left side surface portion of the cover window 11, and a right side surface portion facing the right side surface portion of the cover window 11. The left side surface portion of the display device 100 may extend from a left side of the upper surface portion, and the right side surface portion may extend from a right side of the upper surface portion.

The display device 100 may include the main area MA which serves as a display surface and the sub-area SBA which protrudes from at least a portion of a side of the main area MA.

The main area MA may include the display area DA which displays an image and the non-display area NDA around the display area DA along an edge or a periphery of the display area DA.

The display area DA may be located in most of the main area MA. The display area DA may be located in the center of the main area MA.

In other words, each of the upper surface portion, the left side surface portion, and the right side surface of the display device 100 may include the display area DA and the non-display area NDA.

The display area DA may be located in most of each of the upper surface portion, the left side surface portion, and the right side surface portion of the display device 100.

The non-display area NDA may be located outside the display area DA. The non-display area NDA may be an edge area of the main area MA.

The non-display area NDA may be located at an upper edge and lower edge of the upper surface portion of the display device 100, at an upper edge, left edge and lower edge of the left side surface portion of the display device 10, and at an upper edge, right edge and lower edge of the right side surface portion of the display device 100.

The sub-area SBA may protrude from a side of the main area MA in the second direction D2.

A length of the sub-area SBA in the first direction D1 may be equal to or smaller than a length of the main area MA in the first direction D1. A length of the sub-area SBA in the second direction D2 may be smaller than a length of the main area MA in the second direction D2, but the present disclosure is not limited to this case.

As a portion of the sub-area SBA is changed into a bent shape, the other portion of the sub-area SBA may be overlapped by the main area MA in the third direction D3.

The display driving circuit 200 may be mounted on the sub-area SBA, and the display circuit board 300 may be attached to the sub-area SBA.

An end of the display circuit board 300 may be attached onto pads located at a lower edge of the sub-area SBA of the display device 100 using an anisotropic conductive film.

The display circuit board 300 may be a flexible printed circuit board (FPCB) that can be bent, a rigid printed circuit board (PCB) that maintains a flat shape, or a composite printed circuit board including both a rigid printed circuit board and a flexible printed circuit board.

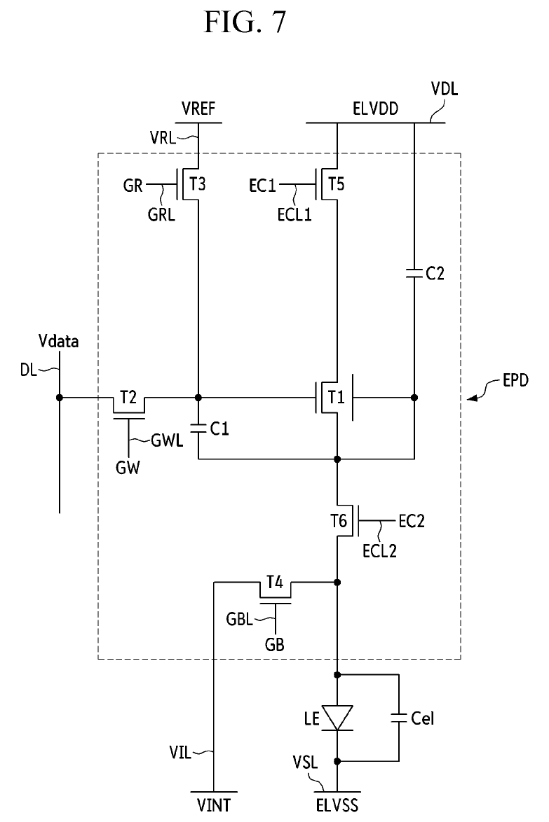

The display driving circuit 200 may transmit respective data signals Vdata (see FIG. 7) of subpixel circuits EPD (see FIG. 7) of the display area DA to data lines DL (see FIG. 7) based on control signals, powers, and voltages supplied through the display circuit board 300.

The display driving circuit 200 may be provided as an integrated circuit and may be mounted on the sub-area SBA of the display device 100 using a chip on glass (COG) method, a chip on plastic (COP) method, or an ultrasonic method. However, this is merely an example, and the present disclosure is not limited to this example. For example, the display driving circuit 200 may also be mounted on the display circuit board 300.

According to one or more embodiments, the touch driving circuit 400 may be further mounted on the sub-area SBA of the display device 100. Alternatively, the touch driving circuit 400 may be mounted on the display circuit board 300.

The touch driving circuit 400 may be electrically connected to a touch sensor layer of the display device 100.

The bracket 13 may be located under the display device 100. The bracket 13 may include plastic and/or metal. The bracket 13 may include a first camera hole CMH1 into which a camera device 16 is inserted, a battery hole BH in which a battery 18 is placed, and a cable hole CAH through which the cable 600 connected to the display circuit board 300 passes.

The main circuit board 14 and the battery 18 may be located under the bracket 13.

The main circuit board 14 may be a printed circuit board (PCB) or a flexible printed circuit board (FPCB).

The main circuit board 14 may include a main processor 15, the camera device 16, and a main connector 17. The main processor 15 may be formed as an integrated circuit (IC).

The camera device 16 may be located on both an upper surface and a lower surface of the main circuit board 14. The main processor 15 may be located on the upper surface of the main circuit board 14, and the main connector 17 may be located on the lower surface of the main circuit board 14.

The main processor 15 may control all functions of the electronic device 10.

For example, the main processor 15 may output digital video data to the display driving circuit 200 through the display circuit board 300 so that the display device 100 can display an image. In addition, the main processor 15 may receive touch data including a user’s touch coordinates from the touch driving circuit 400, determine whether the user has touched or is in proximity, and then perform an operation corresponding to the user’s touch input or proximity input. For example, the main processor 15 may execute an application or perform an operation indicated by an icon touched by the user.

The main processor 15 may be an application processor, a central processing unit (CPU), or a system chip formed as an integrated circuit.

The camera device 16 processes an image frame such as a still image and/or a moving image obtained by an image sensor in a camera mode and outputs the processed image frame to the main processor 15.

The cable 600 passing through the cable hole CAH of the bracket 13 may be connected to the main connector 17. Accordingly, the main circuit board 14 may be electrically connected to the display circuit board 300.

The battery 18 may not overlap the main circuit board 14 in the third direction D3. The battery 18 may overlap the battery hole BH of the bracket 13 in the third direction D3.

In addition, the main circuit board 14 may be further equipped with a mobile communication module that can transmit and receive wireless signals to and from at least one of a base station, an external terminal, and a server over a mobile communication network. The wireless signals may include voice signals, video call signals, or various types of data resulting from transmission/reception of text/multimedia messages.

The bottom cover 12 may be located under the main circuit board 14 and the battery 18. The bottom cover 12 may be fastened and fixed to the bracket 13. The bottom cover 12 may form an upper side surface, a lower side surface, and a lower surface of the electronic device 10. The bottom cover 12 may include plastic, metal, or both plastic and metal.

The bottom cover 12 may include a second camera hole CMH2 which exposes a lower surface of the camera device 16. The position of the camera device 16 and the positions of the first camera hole CMH1 and the second camera hole CMH2 corresponding to the camera device 16 are not limited to those illustrated in the drawing.

Next, a display device 100 according to one or more embodiments will be described.

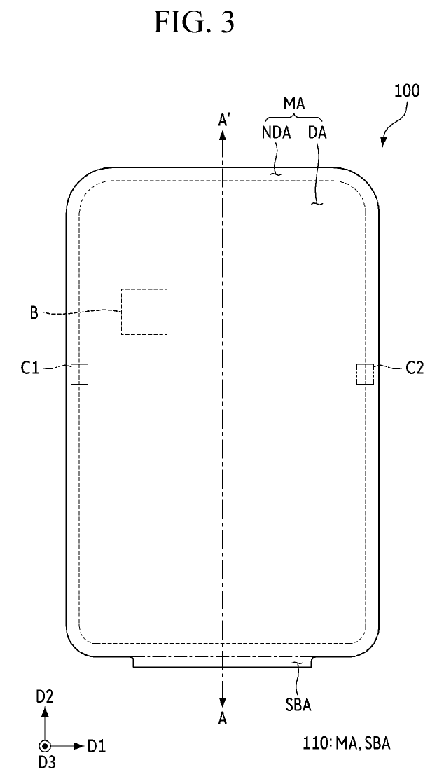

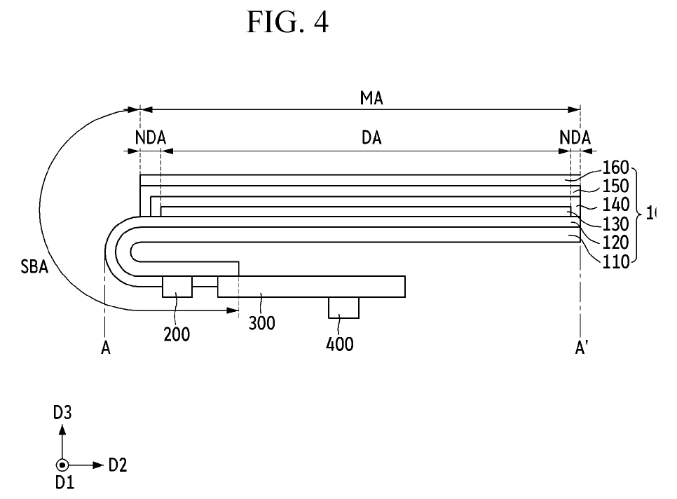

FIG. 3 is a plan view of the display device 100 of FIG. 2. FIG. 4 is a cross-sectional view taken along the line A-A’ of FIG. 3.

Referring to FIGS. 3 and 4, a display device 100 according to one or more embodiments is a device for displaying moving images and/or still images. The display device 100 may be used as a display screen in portable electronic devices such as mobile phones, smartphones, tablet PCs, smart watches, watch phones, mobile communication terminals, electronic notebooks, electronic books, PMPs, navigation devices and UMPCs, as well as in various products such as televisions, notebook computers, monitors, billboards, and/or IoT devices.

The display device 100 may be a light emitting display device such as an organic light emitting display device using an organic light emitting diode (OLED), a quantum dot light emitting display device including a quantum dot light emitting layer, an inorganic light emitting display device including an inorganic semiconductor, or a micro- or nano-light emitting display device using a micro- or nano-light emitting diode. A case where the display device 100 is an organic light emitting display device will be mainly described below. However, the present disclosure is not limited to this case. The present disclosure is also applicable to display devices including an organic insulating material, an organic light emitting material, and a metal material.

The display device 100 may be formed flat, but the present disclosure is not limited to this case. For example, the display device 100 may include a curved portion formed at left and right ends and having a constant or varying curvature. In addition, the display device 100 may be formed to be flexible so that it can be curved, bent, folded, and/or rolled.

Referring to FIG. 3, at least a surface of the display device 100 includes the main area MA which emits light for image display.

The display area DA may be shaped like a rectangular plane having short sides in the first direction D1 and long sides in the second direction D2 intersecting the first direction D1. Each corner where a short side extending in the first direction D1 meets a long side extending in the second direction D2 may be rounded to have a selected curvature or may be right-angled. The planar shape of the display area DA is not limited to a quadrangular shape but may also be other polygonal shapes, a circular shape, or an oval shape.

The display area DA may be located in most of the main area MA. The display area DA may be located in the center of the main area MA.

Referring to FIG. 4, the display device 100 may further include the sub-area SBA protruding in the second direction D2 from at least a portion of a side of the main area MA.

As a portion of the sub-area SBA is changed into a bent shape, the other portion of the sub-area SBA may be placed on a back surface of the display device 100.

According to one or more embodiments, the display device 100 includes a substrate 110, a circuit layer 120 located on the substrate 110, and an element layer 130 located on the circuit layer 120.

The display device 100 may further include a sealing layer 140 located on the element layer 130 and a touch sensor layer 150 located on the sealing layer 140.

The display device 100 may further include a polarizing layer 160 located on the touch sensor layer 150 to reduce reflection of external light.

The substrate 110 may include the main area MA corresponding to the display surface and the sub-area SBA protruding in the second direction D2 from at least a portion of a side of the main area MA.

The main area MA of the substrate 110 may include the display area DA for emitting light and the non-display area NDA located around the display area DA.

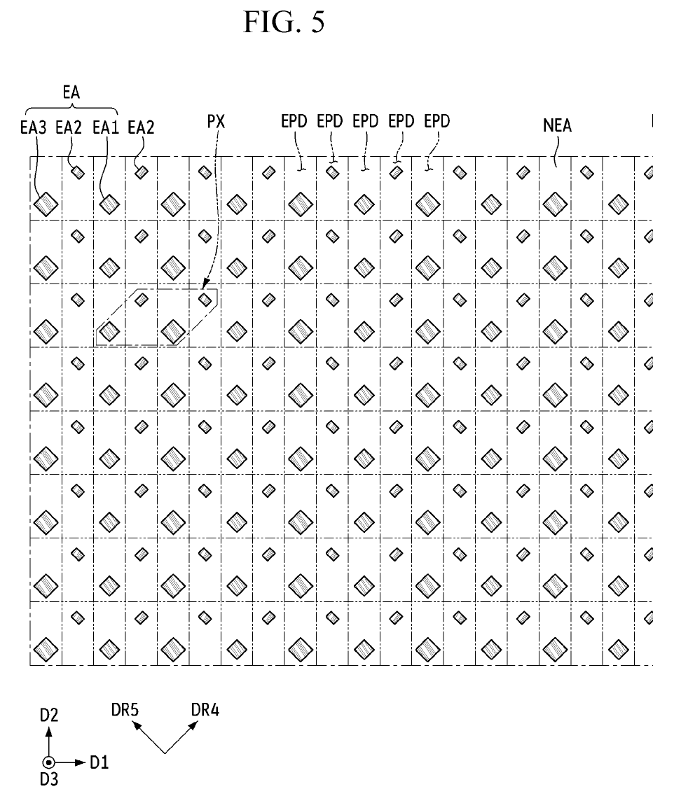

According to one or more embodiments, the element layer 130 may include light emitting elements LE (see FIG. 7) located in emission areas EA (see FIG. 5), respectively.

The circuit layer 120 may include subpixel circuits EPD (see FIG. 5) electrically connected to the light emitting elements LE and one or more constant voltage lines for transmitting one or more constant voltages to the subpixel circuits EPD.

The constant voltage lines may include a first driving voltage line VDL (see FIG. 7) which transmits a first driving voltage ELVDD (see FIG. 7), an initialization voltage line VIL (see FIG. 7) which transmits an initialization voltage VINT (see FIG. 7), and a reference voltage line VRL (see FIG. 7) which transmits a reference voltage VREF (see FIG. 7).

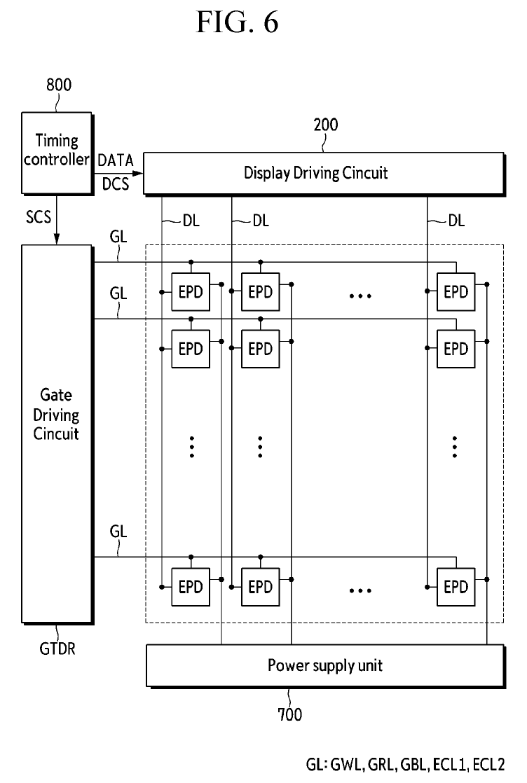

The circuit layer 120 may further include data lines DL (see FIGS. 6 and 7) which transmit data signals Vdata (see FIG. 7) to the subpixel circuits EPD (see FIG. 5).

The sealing layer 140 may cover the element layer 130. The sealing layer 140 may include a structure in which two or more inorganic layers and at least one organic layer are alternately stacked.

The touch sensor layer 150 may be located on the sealing layer 140 and may correspond to the main area MA. The touch sensor layer 150 may include touch electrodes for detecting a touch of a person or an object.

The polarizing layer 160 blocks external light reflected from the touch sensor layer 150, the sealing layer 140, the element layer 130, the circuit layer 120 and interfaces between the touch sensor layer 150, the sealing layer 140, the element layer 130 and the circuit layer 120 to prevent a reduction in image visibility due to reflection of the external light.

As a portion of the sub-area SBA is changed into a bent shape, the display driving circuit 200 mounted on the sub-area SBA and the display circuit board 300 connected to a side of the sub-area SBA may be placed under the substrate 110.

The display driving circuit 200 may be electrically connected to the data lines DL (see FIGS. 6 and 7) of the circuit layer 120. The display driving circuit 200 may transmit the data signals Vdata (see FIG. 7) to the subpixel circuits EPD (see FIG. 5) through the data lines DL based on control signals and power voltages supplied from the display circuit board 300.

The display driving circuit 200 may be provided as an integrated circuit (IC) and may be mounted on the sub-area SBA of the display device 100 using a COG method, a COP method, and/or an ultrasonic method. However, this is merely an example, and the present disclosure is not limited to this example. For example, the display driving circuit 200 may also be mounted on the display circuit board 300.

An end of the display circuit board 300 may be attached onto pads located at an edge of the sub-area SBA of the display device 100 using an anisotropic conductive film.

The display circuit board 300 may be a flexible printed circuit board (FPCB) that can be bent, a rigid printed circuit board that maintains a flat shape, or a composite printed circuit board including both a rigid printed circuit board and a flexible printed circuit board.

The display circuit board 300 may be connected to signal pads located at a side of the sub-area SBA.

The touch driving circuit 400 may be mounted on the display circuit board 300.

The touch driving circuit 400 may be electrically connected to the touch sensor layer 150 of the display device 100.

The touch driving circuit 400 may apply touch driving signals to driving lines of the touch sensor layer 150 and receive touch sensing signals from sensing lines. In addition, the touch driving circuit 400 may determine whether a user’s touch or proximity has occurred by sensing amounts of charge change in capacitances based on the touch sensing signals.

The user’s touch indicates that an object, such as the user’s finger or a pen, directly touches an upper surface of the cover window located on the touch sensor layer. The user’s proximity indicates that an object, such as the user’s finger or a pen, hovers above the upper surface of the cover window.

The touch driving circuit 400 may output touch data including the user’s touch coordinates to the main processor 15 (see FIG. 2).

FIG. 5 is a plan view of a portion B of FIG. 3.

As illustrated in FIG. 5, the display area DA may include emission areas EA which emit light and a non-emission area NEA which is an area between the emission areas EA and does not emit light.

Each of the emission areas EA may be a unit area that emits light of a wavelength band corresponding to one of two or more different colors with a luminance corresponding to an image signal.

Each of the emission areas EA may have a quadrangular shape.

However, this is merely an example, and the planar shape of each emission area EA according to one or more embodiments is not limited to the shape illustrated in FIG. 5. That is, the emission areas EA may also have a non-rhombic polygonal shape, such as a rectangle, a square, a hexagon or an octagon, a circular shape, or an oval shape in a plan view.

The emission areas EA may include first emission areas EA1 for emitting light of a first wavelength band, second emission areas EA2 for emitting light of a second wavelength band lower than the first wavelength band, and third emission areas EA3 for emitting light of a third wavelength band lower than the second wavelength band.

For example, the first wavelength band may be about 600 nm to about 750 nm and may correspond to red. The second wavelength band may be about 480 nm to about 560 nm and may correspond to green. The third wavelength band may be about 370 nm to about 460 nm and may correspond to blue.

However, this is merely an example, and the first wavelength band, the second wavelength band, and the third wavelength band according to one or more embodiments are not limited to this example.

Because the emission areas EA include the first emission areas EA1, the second emission areas EA2, and the third emission areas EA3, unit pixels PX may each be formed by a combination of one or more first emission areas EA1, one or more second emission areas EA2, and one or more third emission areas EA3 adjacent to each other among the emission areas EA.

Each of the unit pixels PX may be a unit that displays various colors including white. That is, light of various colors displayed by each unit pixel PX may be realized as a mixture of light emitted from two or more emission areas EA included in each unit pixel PX.

The third emission areas EA3 may have a greater width than the first emission areas EA1, and the first emission areas EA1 may have a greater width than the second emission areas EA2. However, this is merely an example, and the width of each of the emission areas EA is not limited to the width illustrated in FIG. 5.

The first emission areas EA1 and the third emission areas EA3 may be alternately arranged along the first direction D1.

The second emission areas EA2 may be arranged side by side along the second direction D2.

Each of the second emission areas EA2 may neighbor a first emission area EA1 or a third emission area EA3 in diagonal directions DR4 and DR5 intersecting the first direction D1 and the second direction D2.

In this case, each of the unit pixels PX may include one first emission area EA1 and one third emission area EA3 neighboring each other in the first direction D1 and two second emission areas EA2 neighboring the first emission area EA1 and the third emission area EA3 in the diagonal directions DR4 and DR5. However, this is merely an example, and the arrangement of the emission areas EA according to one or more embodiments and the elements of each unit pixel PX are not limited to the above description.

According to one or more embodiments, the circuit layer 120 (see FIG. 4) may include subpixel circuits EPD arranged in the display area DA along the first direction D1 and the second direction D2.

The subpixel circuits EPD may be electrically connected to light emitting elements LE (see FIG. 7) of the element layer 130 (see FIG. 4), respectively. The light emitting elements LE may be located in the emission areas EA, respectively.

FIG. 6 is a block diagram of the display device 100 of FIG. 2.

Referring to FIG. 6, the circuit layer 120 of the display device 100 according to one or more embodiments may include subpixel circuits EPD electrically connected to the light emitting elements LE (see FIG. 7) located in the emission areas EA of the display area DA and one or more gate lines GL for transmitting one or more gate signals to the subpixel circuits EPD.

The circuit layer 120 may further include data lines DL, which transmit data signals Vdata (see FIG. 7) to the subpixel circuits EPD.

According to one or more embodiments, the display device 100 may further include the display driving circuit 200 which outputs the data signals Vdata (see FIG. 7) to the subpixel circuits EPD to the data lines DL to control the luminance of each of the light emitting elements LE (see FIG. 7).

According to one or more embodiments, the display device 100 may further include a gate driving circuit GTDR that outputs gate signals to the gate lines GL, a power supply unit 700 that supplies powers and voltages to the subpixel circuits EPD, and a timing controller 800 that controls the driving timing of each of the display driving circuit 200 and the gate driving circuit GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driving circuit GTDR.

The display driving circuit 200 may convert the image data DATA into analog data voltages and output the analog data voltages to the data lines DL.

The gate driving circuit GTDR may generate gate signals according to the scan control signal SCS and sequentially output the gate signals to the gate lines GL.

The gate lines GL may include a write scan line GWL that transmits a write scan signal GW (see FIG. 7), a reset control line GRL that transmits a reset control signal GR (see FIG. 7), a bias scan line GBL that transmits a bias scan signal GB (see FIG. 7), a first emission control line ECL1 that transmits a first emission control signal EC1 (see FIG. 7), and a second emission control line ECL2 that transmits a second emission control signal EC2 (see FIG. 7).

Each of the gate signals may have a pulse that changes to a first gate-level voltage or a second gate-level voltage.

The power supply unit 700 may supply various powers and voltages necessary for driving the subpixel circuits EPD.

For example, the power supply unit 700 may supply a first driving voltage ELVDD (see FIG. 7) and second power ELVSS (see FIG. 7) for generating a driving signal to be transmitted to the light emitting elements LE, a reference voltage VREF (see FIG. 7) for initializing the subpixel circuits EPD, and an initialization voltage VINT (see FIG. 7) for initializing the light emitting elements LE (see FIG. 7).

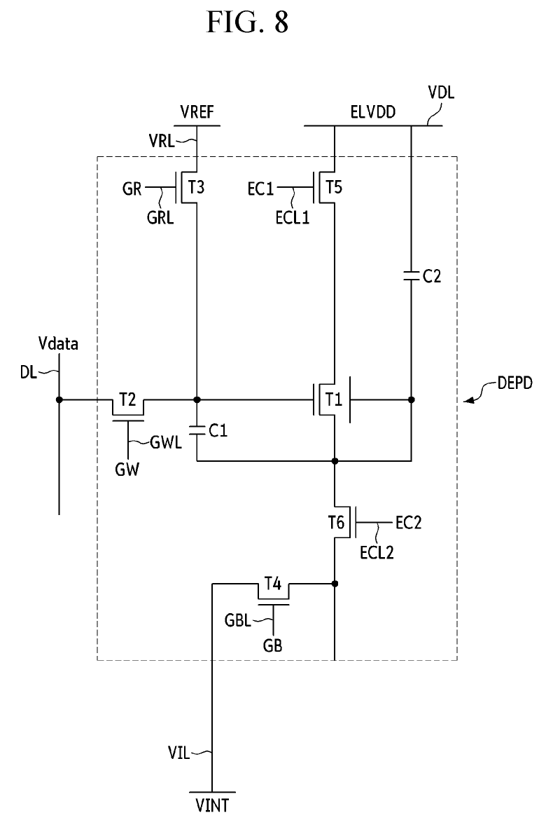

FIG. 7 is an equivalent circuit diagram of a subpixel circuit EPD according to one or more embodiments of the present disclosure. FIG. 8 is an equivalent circuit diagram of a dummy subpixel circuit DEPD according to one or more embodiments of the present disclosure.

A circuit disclosed in the present specification may include a plurality of transistors. Each of the transistors may be an oxide thin-film transistor (TFT) including an oxide semiconductor or a low-temperature polysilicon (LTPS) TFT including LTPS.

A transistor is a three-electrode switching element including a gate, a source, and a drain. The source is an electrode that supplies carriers to the transistor. In the transistor, the carriers start to flow from the source. The drain is an electrode through which the carriers exit the transistor. In the transistor, the carriers flow from the source to the drain.

In the case of an n-channel transistor, the carriers are electrons. Therefore, a source voltage is lower than a drain voltage so that the electrons can flow from the source to the drain. In the n-channel transistor, a current flows from the drain to the source. In the case of a p-channel transistor, the carriers are holes. Therefore, the source voltage is higher than the drain voltage so that the holes can flow from the source to the drain. In the p-channel transistor, because the holes flow from the source to the drain, a current flows from the source to the drain. It should be noted that the source and drain of the transistor are not fixed. For example, the source and the drain can be changed depending on an applied voltage. Therefore, the present disclosure is not limited by the source and drain of the transistor.

In the following description, a first electrode, a second electrode, and a gate electrode of a transistor may all be referred to as electrodes of the transistor. In addition, a source electrode and a drain electrode of the transistor may be referred to as the first electrode and the second electrode, respectively. For example, a transistor may include the first electrode and the second electrode. If the first electrode of the transistor is a source electrode, the second electrode of the transistor may be a drain electrode. If the second electrode of the transistor is a source electrode, the first electrode of the transistor may be a drain electrode. The distinction between the source and the drain varies depending on whether the transistor is implemented as an n-channel transistor or a p-channel transistor. In the present specification, the terms “first electrode” and “second electrode” are used regardless of whether a transistor is an n-channel transistor or a p-channel transistor.

Referring to FIG. 7, subpixel circuits EPD may be electrically connected to light emitting elements LE. The subpixel circuits EPD may be electrically connected to a first driving voltage line VDL that transmits a first driving voltage ELVDD, and the light emitting elements LE may be electrically connected to a second power line VSL that transmits a second driving voltage ELVSS different from the first driving voltage ELVDD. The second driving voltage ELVSS may have a lower voltage level than the first driving voltage ELVDD.

An anode of a light emitting element LE may be electrically connected to a subpixel circuit EPD, and a cathode of the light emitting element LE may be electrically connected to the second power line VSL. The subpixel circuit EPD may also be electrically connected to a data line DL that transmits a data signal Vdata, a reference voltage line VRL that transmits a reference voltage VREF, and an initialization voltage line VIL that transmits an initialization voltage VINT.

The subpixel circuit EPD may be electrically connected to a write scan line GWL that transmits a write scan signal GW, a reset control line GRL that transmits a reset control signal GR, a bias scan line GBL that transmits a bias scan signal GB, a first emission control line ECL1 that transmits a first emission control signal EC1, and a second emission control line ECL2 that transmits a second emission control signal EC2.

The subpixel circuit EPD may include a first transistor T1 that generates a driving current of the light emitting element LE, two or more transistors T2 through T6 that are electrically connected to the first transistor T1, and one or more capacitors C1 and C2.

A second transistor T2 may be electrically connected between a gate electrode of the first transistor T1 and the data line DL. The second transistor T2 may be turned on by the write scan signal GW of the write scan line GWL. When the second transistor T2 is turned on, the data signal Vdata from the data line DL may be transmitted to the gate electrode of the first transistor T1.

When a voltage difference between the gate electrode of the first transistor T1 and a first electrode (e.g., a source electrode) of the first transistor T1 becomes equal to or greater than a threshold voltage of the first transistor T1 due to the data signal Vdata applied to the gate electrode of the first transistor T1, the first transistor T1 may be turned on. Accordingly, a drain-source current of the first transistor T1 may be generated with a magnitude corresponding to the data signal Vdata.

A third transistor T3 may be electrically connected between the gate electrode of the first transistor T1 and the reference voltage line VRL. The third transistor T3 may be turned on by the reset control signal GR from the reset control line GRL. When the third transistor T3 is turned on, the potential of the gate electrode of the first transistor T1 may be initialized to the reference voltage VREF of the reference voltage line VRL.

A fourth transistor T4 may be electrically connected between the light emitting element LE and the initialization voltage line VIL. The fourth transistor T4 may be turned on by the bias scan signal GB of the bias scan line GBL. When the fourth transistor T4 is turned on, the potential of the anode of the light emitting element LE may be initialized to the initialization voltage VINT of the initialization voltage line VIL.

A fifth transistor T5 may be electrically connected between a second electrode of the first transistor T1 and the first driving voltage line VDL. The fifth transistor T5 may be turned on by the first emission control signal EC1 from the first emission control line ECL1.

A sixth transistor T6 may be electrically connected between the first electrode of the first transistor T1 and the light emitting element LE. The sixth transistor T6 may be turned on by the second emission control signal EC2 from the second emission control line ECL2.

When the fifth transistor T5 and the sixth transistor T6 are turned on, the first transistor T1 and the light emitting element LE are connected in series between the first driving voltage ELVDD and the second driving voltage ELVSS. Therefore, the drain-source current (or driving current) of the first transistor T1, which is generated with a magnitude corresponding to the data signal Vdata, may be transmitted to the light emitting element LE. Accordingly, the light emitting element LE may emit light with a luminance corresponding to the data signal Vdata.

A first capacitor C1 may be electrically connected between the gate electrode of the first transistor T1 and the first electrode of the first transistor T1. Accordingly, the first capacitor C1 may be charged with the data signal Vdata applied to the gate electrode of the first transistor T1, and the first transistor T1 may remain turned on for a selected period of time due to the voltage that charges the first capacitor C1.

A second capacitor C2 may be electrically connected between the first electrode of the first transistor T1 and the first driving voltage line VDL. The voltage of the first capacitor C1 may correspond to a potential difference between the gate electrode of the first transistor T1 and the first electrode of the first transistor T1, may be changed by the data signal Vdata, and may be divided by the second capacitor C2. Accordingly, the threshold voltage of the first transistor T1 may be compensated.

According to one or more embodiments, the first transistor T1 may include a gate electrode facing a surface of a channel portion and a gate additional electrode facing another surface of the channel portion. The channel portion of the first transistor T1 may be located between the gate electrode and the gate additional electrode of the first transistor T1.

The gate electrode of the first transistor T1 may be electrically connected to the second transistor T2. A back-gate electrode of the first transistor T1 may be electrically connected to the first electrode of the first transistor T1.

Accordingly, when the first transistor T1 is turned on in response to the data signal Vdata applied to the gate electrode of the first transistor T1, at least a portion of the channel portion of the first transistor T1, which is adjacent to the gate electrode, may be activated, whereas the other portion of the channel portion of the first transistor T1, which is adjacent to the gate additional electrode, is not activated.

Therefore, the electron mobility in the channel portion of the first transistor T1 may be reduced, and the slope of a current curve representing the relationship between the voltage of the gate electrode of the first transistor T1 and the source-drain current may become gentle. Accordingly, the driving voltage range of the first transistor T1 may be widened, thereby improving the ease of luminance control.

According to one or more embodiments, the first through sixth transistors T1 through T6 may be n-channel transistors. However, the present disclosure is not limited to this case.

In one or more embodiments, the first transistor T1 may be an oxide TFT including an oxide semiconductor. Compared with an LTPS TFT, an oxide TFT has similar threshold voltages between pixels. Therefore, when an oxide TFT is used as a driving transistor, uniformity related to threshold voltage characteristics of the driving transistor across the entire screen can be improved. The second through sixth transistors T2 through T6 may also be oxide TFTs including oxide semiconductors, but the present disclosure is not limited to this case.

Referring to FIG. 8, the dummy subpixel circuit DEPD according to one or more embodiments of the present disclosure may include elements similar to those of the subpixel circuit EPD according to the embodiment described above. For example, like the subpixel circuit EPD, the dummy subpixel circuit DEPD may include first through sixth transistors T1 through T6, a plurality of scan lines, a plurality of emission control lines, a plurality of constant voltage lines, and a plurality of capacitors. However, the dummy subpixel circuit DEPD may be distinguished from the subpixel circuit DEPD in that it does not include a light emitting element ED.

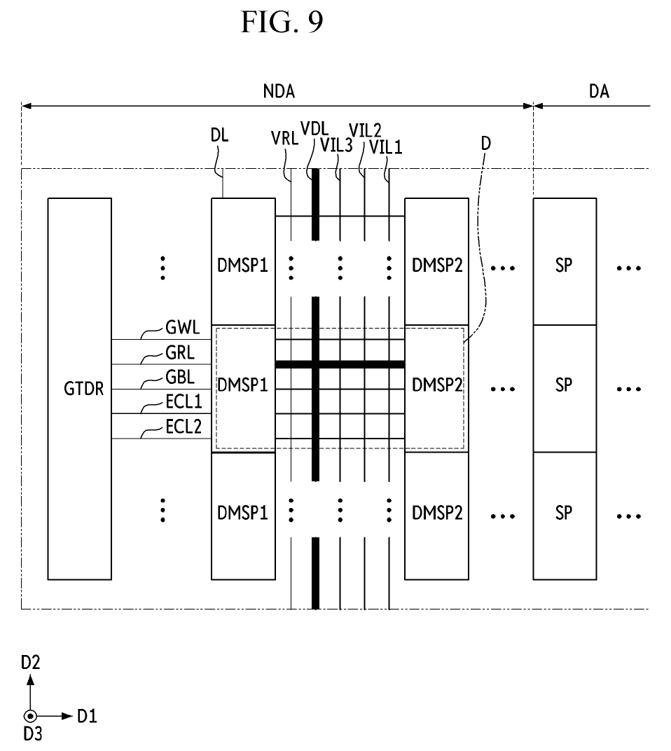

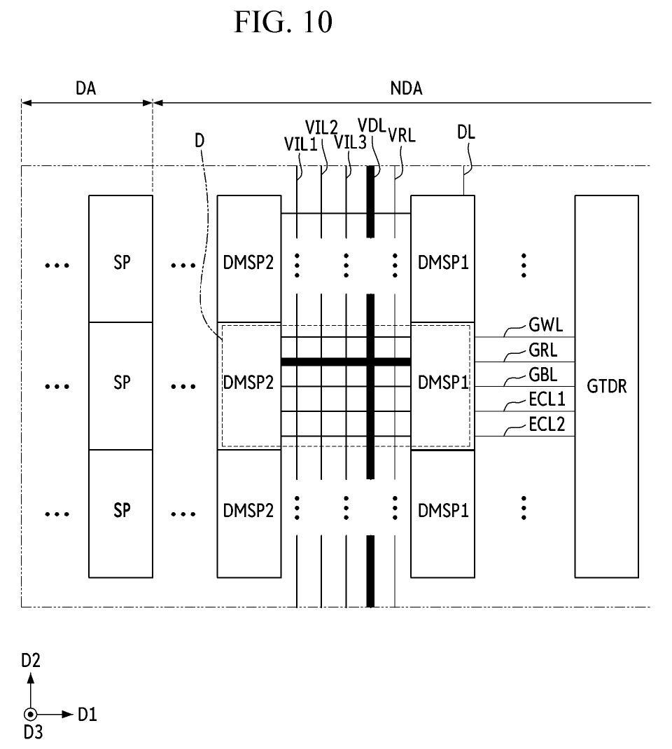

FIGS. 9 and 10 are plan views of a display device according to one or more embodiments of the present disclosure. FIGS. 9 and 10 are also enlarged views of portions C1 and C2 of FIG. 3, respectively.

Referring to FIGS. 9 and 10, a plurality of scan signals, a plurality of emission control signals, and a plurality of constant voltages may be supplied to subpixels SP and dummy subpixels DMSP1 and DMSP2 included in the display device according to one or more embodiments of the present disclosure.

The scan signals may include a write scan signal, a reset control signal, and a bias scan signal. The emission control signals may include a first emission control signal and a second emission control signal. The constant voltages may include a first driving voltage, a reference voltage, and an initialization voltage.

The subpixels SP located in a display area DA according to the embodiment may include a first subpixel that realizes a first color, a second subpixel that realizes a second color, and a third subpixel that realizes a third color. The first color, the second color, and the third color may each be selected from red, green, and blue such that they do not overlap each other. For example, the first color may be red, the second color may be green, and the third color may be blue, but the present disclosure is not limited to this example. The subpixels SP may further include a fourth subpixel that realizes white.

The initialization voltage may include a first initialization voltage, a second initialization voltage, and a third initialization voltage. The first initialization voltage may be applied to the first subpixel, the second initialization voltage may be applied to the second subpixel, and the third initialization voltage may be applied to the third subpixel. For example, the first initialization voltage may be applied to a fourth transistor T4 of the first subpixel, the second initialization voltage may be applied to a fourth transistor T4 of the second subpixel, and the third initialization voltage may be applied to a fourth transistor T4 of the third subpixel. The first through third initialization voltages may all have the same potential or different potentials.

The display device according to the present embodiment may further include a plurality of dummy subpixels DMSP1 and DMSP2 located in a non-display area NDA, in addition to the subpixels SP located in the display area DA. The dummy subpixels DMSP1 and DMSP2 may include first dummy subpixels DMSP1 located between a gate driving circuit GTDR and the subpixels SP and second dummy subpixels DMSP2 located between the first dummy subpixels DMSP1 and the subpixels SP.

Constant voltage lines that supply constant voltages to the display device according to one or more embodiments may include a first driving voltage line VDL that supplies the first driving voltage, a reference voltage line VRL that supplies the reference voltage, a first initialization voltage line VIL1 that supplies the first initialization voltage, a second initialization voltage line VIL2 that supplies the second initialization voltage, and a third initialization voltage line VIL3 that supplies the third initialization voltage.

According to one or more embodiments, the five constant voltage lines described above may be divided into a first constant voltage line group extending in a first direction D1 and a second constant voltage line group extending in a second direction D2.

The first constant voltage line group and the second constant voltage line group may each include the first driving voltage line VDL that supplies the first driving voltage, the reference voltage line VRL that supplies the reference voltage, the first initialization voltage line VIL1that supplies the first initialization voltage, the second initialization voltage line VIL2 that supplies the second initialization voltage, and the third initialization voltage line VIL3 that supplies the third initialization voltage.

The second constant voltage line group may be located between the first dummy subpixels DMSP1 and the second dummy subpixels DMSP2.

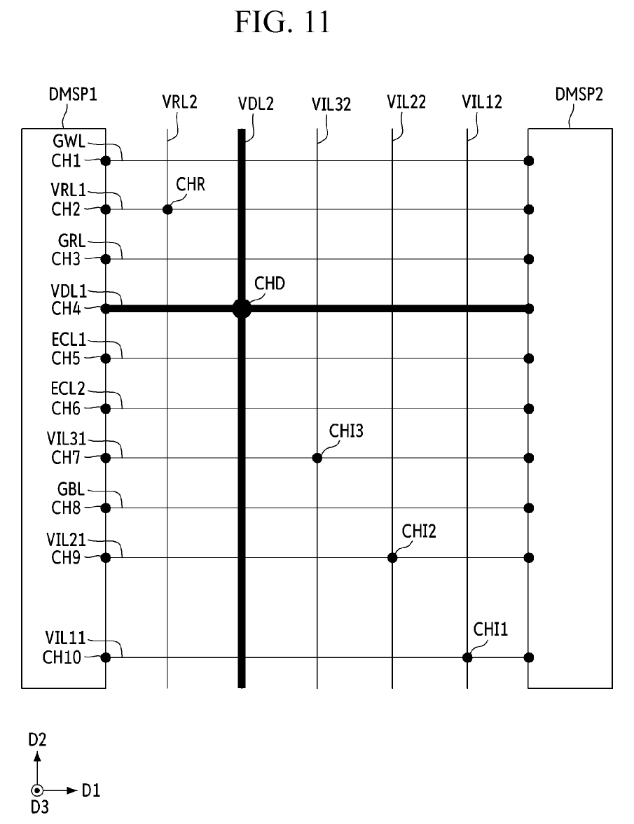

The first constant voltage line group may be electrically connected to the first dummy subpixels DMSP1 and the second dummy subpixels DMSP2 through a plurality of contact holes (e.g., a first contact hole CH1, a second contact hole CH2, a third contact hole CH3, a fourth contact hole CH4, a fifth contact hole CH5, a sixth contact hole CH6, a seventh contact hole CH7, an eighth contact hole CH8, a ninth contact hole CH9, and a tenth contact hole CH10 of FIG. 11). Specifically, the second constant voltage line group may be located in an area between a plurality of contact holes connecting the first dummy subpixels DMSP1 and the first constant voltage line group and a plurality of contact holes connecting the second dummy subpixels DMSP2 and the first constant voltage line group.

In the conventional art, both the first constant voltage line group and the second constant voltage line group are formed in (e.g., at) the same layer. Because the second constant voltage line group supplies a constant voltage to all of the subpixels SP or the dummy subpixels DMSP1 and DMSP2 arranged along the second direction D2, the second constant voltage line group needs to be electrically connected to the first constant voltage line group through a plurality of contact holes. However, when both the first constant voltage line group and the second constant voltage line group are formed in (e.g., at) the same layer, the five constant voltage lines described above cannot all be placed on a side of the non-display area NDA to secure a sufficient area in which the contact holes are to be placed. For example, in a conventional display device, the reference voltage line VRL, the first driving voltage line VDL, and the first initialization voltage line VIL1 are placed in portion C1 of FIG. 3, and the reference voltage line VRL, the first driving voltage line VDL, the second initialization voltage line VIL2, and the third initialization voltage line VIL3 are placed in portion C2 of FIG. 3. In other words, because some power lines cannot be allocated to a side of the display device, the structure of the lines located in the display area DA becomes complicated, and an applied voltage is not constant.

In the display device according to one or more embodiments of the present disclosure, a design method that can arrange all five constant voltage lines on a side of the display device is provided. Because the five constant voltage lines are arranged on each of one side and the other side of the display device, constant voltage values supplied to the subpixels SP located on one side and the other side of the display area DA can all be stabilized, and display quality can also become uniform throughout the display area DA.

FIG. 11 is a plan view of the display device according to one or more embodiments of the present disclosure. FIG. 11 is also an enlarged view of portion D of FIG. 9.

Referring to FIG. 11, a scan line group, an emission control line group, and a first constant voltage line group may be located between a first dummy subpixel DMSP1 and a second dummy subpixel DMSP2. The scan line group, the emission control line group, and the first constant voltage line group may extend in the first direction D1 between the first dummy subpixel DMSP1 and the second dummy subpixel DMSP2.

A second constant voltage line group may be further located between the first dummy subpixel DMSP1 and the second dummy subpixel DMSP2. The second constant voltage line group may include a plurality of constant voltage lines extending in the second direction D2.

The scan line group may include a write scan line GWL, a reset control line GRL, and a bias scan line GBL. The emission control line group may include a first emission control line ECL1 and a second emission control line ECL2. The first constant voltage line group may include a reference voltage line VRL1 of the first constant voltage line group, a first driving voltage line VDL1 of the first constant voltage line group, a third initialization voltage line VIL31 of the first constant voltage line group, a second initialization voltage line VIL21 of the first constant voltage line group, and a first initialization voltage line VIL11 of the first constant voltage line group.

The second constant voltage line group may include a reference voltage line VRL2 of the second constant voltage line group, a first driving voltage line VDL2 of the second constant voltage line group, a third initialization voltage line VIL32 of the second constant voltage line group, a second initialization voltage line VIL22 of the second constant voltage line group, and a first initialization voltage line VIL12 of the second constant voltage line group.

A reference voltage may be applied to both the reference voltage line VRL1 of the first constant voltage line group and the reference voltage line VRL2 of the second constant voltage line group.

A first driving voltage may be applied to both the first driving voltage line VDL1 of the first constant voltage line group and the first driving voltage line VDL2 of the second constant voltage line group.

A first initialization voltage may be applied to both the first initialization voltage line VIL11 of the first constant voltage line group and the first initialization voltage line VIL12 of the second constant voltage line group.

A second initialization voltage may be applied to both the second initialization voltage line VIL21 of the first constant voltage line group and the second initialization voltage line VIL22 of the second constant voltage line group.

A third initialization voltage may be applied to both the third initialization voltage line VIL31 of the first constant voltage line group and the third initialization voltage line VIL32 of the second constant voltage line group.

The write scan line GWL may be electrically connected to the first dummy subpixel DMSP1 through a first contact hole CH1. The reset control line GRL may be electrically connected to the first dummy subpixel DMSP1 through a third contact hole CH3. The bias scan line GBL may be electrically connected to the first dummy subpixel DMSP1 through an eighth contact hole CH8.

The first emission control line ECL1 may be electrically connected to the first dummy subpixel DMSP1 through a fifth contact hole CH5. The second emission control line ECL2 may be electrically connected to the first dummy subpixel DMSP1 through a sixth contact hole CH6.

The reference voltage line VRL1 of the first constant voltage line group may be electrically connected to the first dummy subpixel DMSP1 through a second contact hole CH2. The first driving voltage line VDL1 of the first constant voltage line group may be electrically connected to the first dummy subpixel DMSP1 through a fourth contact hole CH4. The third initialization voltage line VIL31 of the first constant voltage line group may be electrically connected to the first dummy subpixel DMSP1 through a seventh contact hole CH7. The second initialization voltage line VIL21 of the first constant voltage line group may be electrically connected to the first dummy subpixel DMSP1 through a ninth contact hole CH9. The first initialization voltage line VIL11 of the first constant voltage line group may be electrically connected to the first dummy subpixel DMSP1 through a tenth contact hole CH10.

The reference voltage line VRL2 of the second constant voltage line group may be electrically connected to the reference voltage line VRL1 of the first constant voltage line group through a reference contact hole CHR.

The first driving voltage line VDL2 of the second constant voltage line group may be electrically connected to the first driving voltage line VDL1 of the first constant voltage line group through a driving contact hole CHD.

The first initialization voltage line VIL12 of the second constant voltage line group may be electrically connected to the first initialization voltage line VIL11 of the first constant voltage line group through a first initialization contact hole CHI1.

The second initialization voltage line VIL22 of the second constant voltage line group may be electrically connected to the second initialization voltage line VIL21 of the first constant voltage line group through a second initialization contact hole CHI2.

The third initialization voltage line VIL32 of the second constant voltage line group may be electrically connected to the third initialization voltage line VIL31 of the first constant voltage line group through a third initialization contact hole CHI3.

The first constant voltage line group may supply a constant voltage to all of the subpixels SP and the dummy subpixels DMSP1 and DMSP2 located in a plurality of rows.

The second constant voltage line group may supply a constant voltage to the subpixels SP and the dummy subpixels DMSP1 and DMSP2 located in any one row.

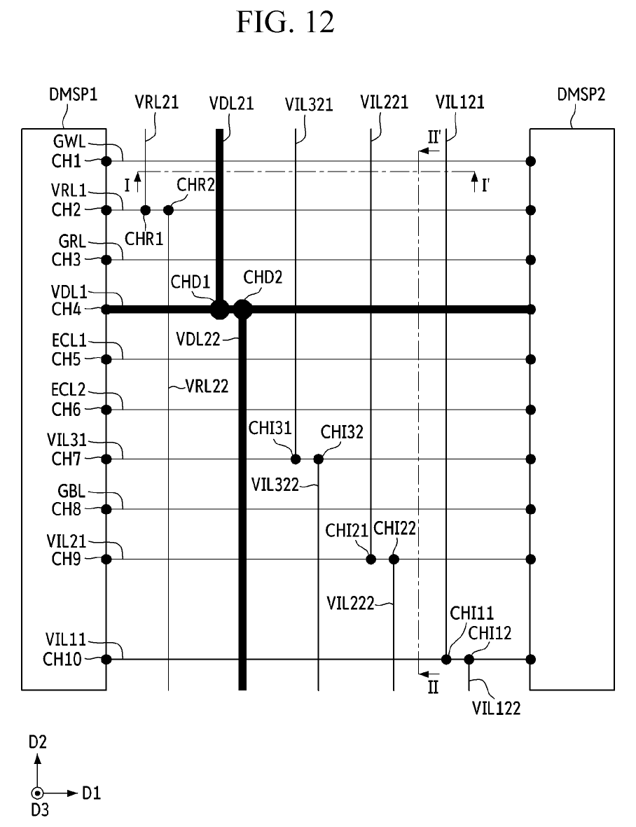

FIG. 12 is a plan view of a display device according to one or more embodiments of the present specification. FIG. 12 is also an enlarged view of a portion D of FIG. 9.

Referring to FIG. 12, a reference voltage line VRL2 of a second constant voltage line group, a first driving voltage line VDL2 of the second constant voltage line group, a third initialization voltage line VIL32 of the second constant voltage line group, a second initialization voltage line VIL22 of the second constant voltage line group, and a first initialization voltage line VIL12 of the second constant voltage line group may each be formed in multiple numbers. For example, the reference voltage line VRL2 of the second constant voltage line group may include a first sub-reference voltage line VRL21 and a second sub-reference voltage line VRL22 that supply a reference voltage.

Constant voltage lines included in the second constant voltage line group supply a constant voltage to all of subpixels SP and dummy subpixels DMSP1 and DMSP2 located in a plurality of rows. Therefore, if the constant voltage is supplied through a single contact hole, the probability of static electricity, etc. occurring during a process of manufacturing the display device may increase. Hence, embodiments of the present disclosure may supply a constant voltage to subpixels SP or dummy subpixels DMSP1 and DMSP2 located in any one row through a plurality of contact holes, thereby improving the stability of the process of manufacturing the display device.

Therefore, a plurality of reference contact holes CHR1 and CHR2 may be formed to electrically connect the reference voltage line VRL2 of the second constant voltage line group to a reference voltage line VRL1 of a first constant voltage line group.

A plurality of driving contact holes CHD1 and CHD2 may be formed to electrically connect the first driving voltage line VDL2 of the second constant voltage line group to a first driving voltage line VDL1 of the first constant voltage line group.

A plurality of first initialization contact holes CHI11 and CHI12 may be formed to electrically connect the first initialization voltage line VIL12 of the second constant voltage line group to a first initialization voltage line VIL11 of the first constant voltage line group.

A plurality of second initialization contact holes CHI21 and CHI22 may be formed to electrically connect the second initialization voltage line VIL22 of the second constant voltage line group to a second initialization voltage line VIL21 of the first constant voltage line group.

A plurality of third initialization contact holes CHI31 and CHI32 may be formed to electrically connect the third initialization voltage line VIL32 of the second constant voltage line group to a third initialization voltage line VIL31 of the first constant voltage line group.

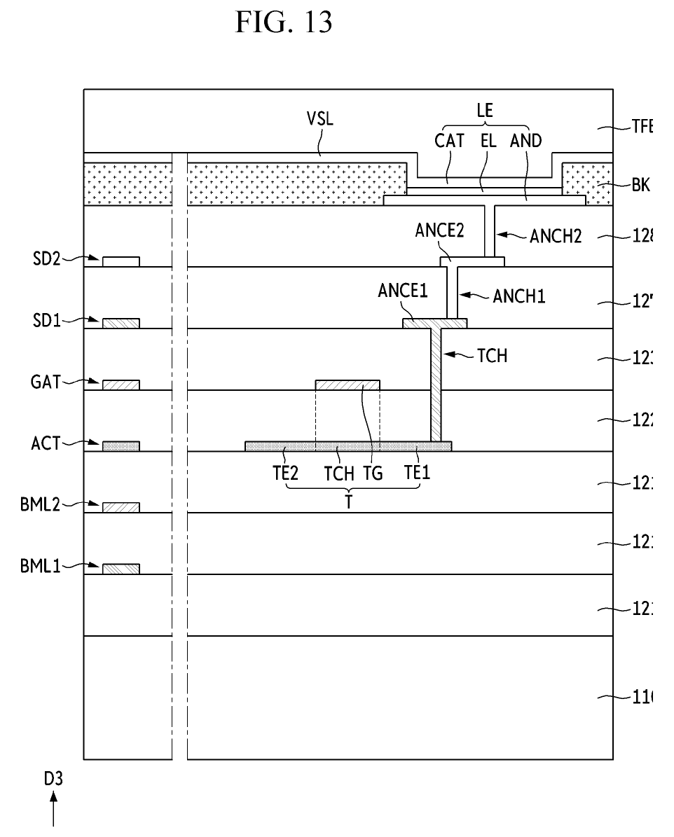

FIG. 13 is a cross-sectional view of a display device according to one or more embodiments of the present disclosure.

Referring to FIG. 13, as described above, a plurality of transistors T1 through T6 are included in a subpixel circuit or a dummy subpixel circuit. A transistor T illustrated in the drawing may correspond to any one of the transistors described above.

The transistor T may include electrodes TE1, TE2, and TG of the transistor T and a channel portion TCH of the transistor T. The electrodes TE1, TE2, and TG of the transistor T may include a first electrode TE1 of the transistor T, a second electrode TE2 of the transistor T, and a gate electrode TG of the transistor T. The channel portion TCH of the transistor T may be located between the first electrode TE1 of the transistor T and the second electrode TE2 of the transistor T and may overlap the gate electrode TG of the transistor T in a third direction D3. As shown in FIG. 13, the channel portion TCH, the first electrode TE1, and the second electrode TE2 of the transistor T may be located on a third buffer layer 121c, and the gate electrode TG of the transistor may be located on a gate insulating layer 122.

The display device according to one or more embodiments of the present disclosure may include a substrate 110 and a plurality of insulating layers. The insulating layers may include a first buffer layer 121a, a second buffer layer 121b, the third buffer layer 121c, the gate insulating layer 122, and an interlayer insulating film 123, but the present disclosure is not limited to this case. The display device may further include a planarization layer (127, 128) located on the insulating layers. The planarization layer may be formed as a multilayer including a first planarization layer 127 and a second planarization layer 128, but the present disclosure is not limited to this case.

The first buffer layer 121a may be formed on the substrate 110 of the display device according to one or more embodiments, and a first bottom metal layer BML1 may be formed on the first buffer layer 121a. A second bottom metal layer BML2 may be formed on the second buffer layer 121b. An active layer ACT may be formed on the third buffer layer 121c. A gate metal layer GAT may be formed on the gate insulating layer 122. A first connection metal layer SD1 may be formed on the interlayer insulating film 123. A second connection metal layer SD2 may be located on the first planarization layer 127.

An element layer may be formed on the second planarization layer 128. The element layer may include a light emitting element LE and a bank BK. The light emitting element LE may include an anode AND, a light emitting layer EL, and a cathode CAT. The bank BK may cover at least a portion of an end portion and/or the other end portion of the anode AND and may define an emission area.

The substrate 110 may include an insulating material such as polymer resin and/or glass. The substrate 110 may include a glass material. The substrate 110 may include polyimide. In this case, the substrate 110 may be a flexible substrate that can be bent, folded, and/or rolled.

The first buffer layer 121a located on the substrate 110 may include a silicon nitride layer, a silicon oxynitride layer, a silicon oxide layer, a titanium oxide layer, and/or an aluminum oxide layer.

The first bottom metal layer BML1 located on the first buffer layer 121a may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The second buffer layer 121b on the first buffer layer 121a and covering the first bottom metal layer BML1 may include a silicon nitride layer, a silicon oxynitride layer, a silicon oxide layer, a titanium oxide layer, and/or an aluminum oxide layer. The second buffer layer 121b may include an inorganic layer that can prevent penetration of air and/or moisture. The second buffer layer 121b may include a plurality of inorganic layers stacked alternately.

The second bottom metal layer BML2 located on the second buffer layer 121b may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The third buffer layer 121c on the second buffer layer 121b and covering the second bottom metal layer BML2 may include a silicon nitride layer, a silicon oxynitride layer, a silicon oxide layer, a titanium oxide layer, and/or an aluminum oxide layer. The third buffer layer 121c may include an inorganic layer that can prevent penetration of air and/or moisture. The third buffer layer 121c may include a plurality of inorganic layers stacked alternately.

The active layer ACT located on the third buffer layer 121c may include an oxide semiconductor. An electrode may be formed when the active layer ACT is doped with ions and/or impurities. The doped active layer ACT may have conductivity.

In one or more embodiments, the active layer ACT may include an oxide semiconductor material. Therefore, all transistors included in the subpixel circuit may be implemented as oxide TFTs.

The gate insulating layer 122 on the third buffer layer 121c and covering the active layer ACT may include an inorganic layer, for example, a silicon nitride layer, a silicon oxynitride layer, a silicon oxide layer, a titanium oxide layer, and/or an aluminum oxide layer.

The gate metal layer GAT located on the gate insulating layer 122 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The interlayer insulating film 123 on the gate insulating layer 122 and covering the gate metal layer GAT may include an inorganic layer, for example, a silicon nitride layer, a silicon oxynitride layer, a silicon oxide layer, a titanium oxide layer, and/or an aluminum oxide layer.

The first connection metal layer SD1 located on the interlayer insulating film 123 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The first planarization layer 127 on the interlayer insulating film 123 and covering the first connection metal layer SD1 may include an organic layer such as acryl resin, epoxy resin, phenolic resin, polyamide resin, and/or polyimide resin.

The second connection metal layer SD2 located on the first planarization layer 127 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The second planarization layer 128 on the first planarization layer 127 and covering the second connection metal layer SD2 may include an organic layer such as acryl resin, epoxy resin, phenolic resin, polyamide resin, and/or polyimide resin.

The light emitting element LE including the anode AND, the light emitting layer EL and the cathode CAT may be located on the second planarization layer 128. The anode AND may be electrically connected or in contact with an anode connection electrode ANCE1 or ANCE2 through an anode contact hole ANCH1 or ANCH2 formed in the first planarization layer 127 or the second planarization layer 128. In one or more embodiments, a first anode connection electrode ANCE1 and a second anode connection electrode ANCE2 may be configured as one anode connection electrode. In this case, the first planarization layer 127 and the second planarization layer 128 may also be configured as one planarization layer. In one or more embodiments, as shown in FIG. 13, the first anode connection electrode ANCE1 may be disposed on the interlayer insulating film 123 and the second anode connection electrode ANCE2 may be disposed on the first planarization layer 127. In one or more embodiments, the first anode connection electrode ANCE1 may be connected to the first electrode TE1 of the transistor T through a contact hole TCH formed in the gate insulating layer 122 and the interlayer insulating film 123.

In a top emission structure in which light is emitted from the light emitting layer EL toward the cathode CAT, the anode AND may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and/or copper (Cu).

The bank BK may be formed on the second planarization layer 128 to delimit the anode AND in order to define an emission area EA. The emission area EA is an area in which the anode AND, the light emitting layer EL, and the cathode CAT are sequentially stacked so that holes from the anode AND and electrons from the cathode CAT are combined with each other in the light emitting layer EL to emit light. The bank BK may cover edges of the anode AND. The bank BK may include an organic layer such as acryl resin, epoxy resin, phenolic resin, polyamide resin, and/or polyimide resin.

The light emitting layer EL may be formed on the anode AND. The light emitting layer EL may include an organic material to emit light of a selected color. For example, the light emitting layer EL may include a hole transporting layer, an organic material layer, and an electron transporting layer.

The cathode CAT may be formed on the light emitting layer EL. The cathode CAT may be formed to cover the light emitting layer EL. The cathode CAT may be a common layer formed in common in all emission areas EA including the illustrated emission area EA (e.g., see FIG. 5). A capping layer may be formed on the cathode CAT.

In the top emission structure, the cathode CAT may include a transparent conductive oxide (TCO) that can transmit light, such as indium tin oxide (ITO) or indium zinc oxide (IZO), or a semi-transmissive conductive material such as magnesium (Mg), silver (Ag), and/or an alloy of Mg and Ag. When the cathode CAT includes a semi-transmissive conductive material, light output efficiency may be increased by a microcavity.

An encapsulating layer TFEL may be located on the cathode CAT. The encapsulating layer TFEL may include at least one inorganic layer to prevent oxygen and/or moisture from permeating into the light emitting element LE. In addition, the encapsulation layer TFEL may include at least one organic layer to protect the light emitting element LE from foreign substances such as dust. For example, the encapsulation layer TFEL may include a plurality of inorganic layers and a single organic layer, but the present disclosure is not limited to this example. The inorganic layer may be a multilayer in which one or more inorganic layers selected from a silicon nitride layer, a silicon oxynitride layer, a silicon oxide layer, a titanium oxide layer, and/or an aluminum oxide layer are alternately stacked. The organic layer may include acryl resin, epoxy resin, phenolic resin, polyamide resin, and/or polyimide resin.

A filling layer, a sealant, and an encapsulation substrate may replace the encapsulation layer TFEL. In this case, the encapsulation substrate may be an insulating substrate including an insulating material such as glass and/or plastic. The filling layer may be, but is not limited to, an air layer in a vacuum state. The sealant may be located in a non-display area of a display panel to be around (e.g., to surround) a display area.

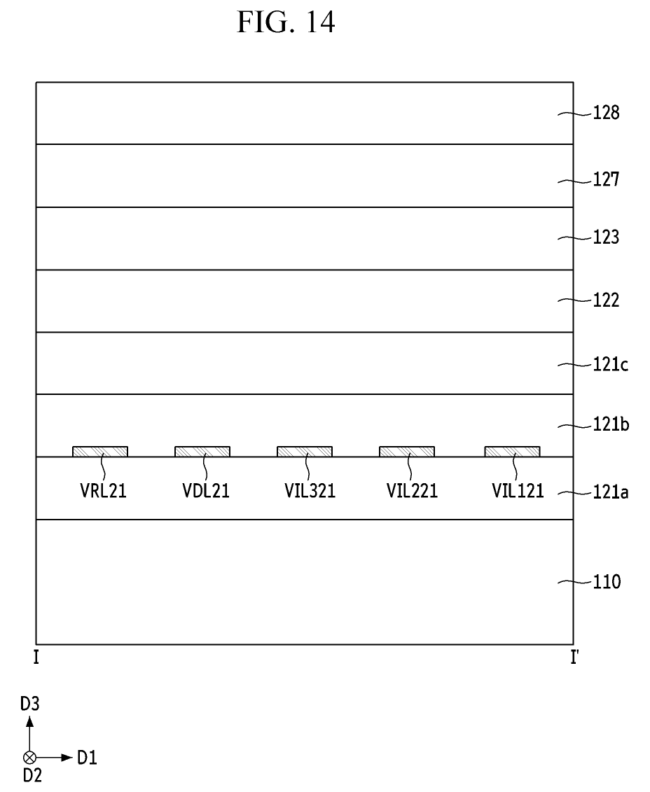

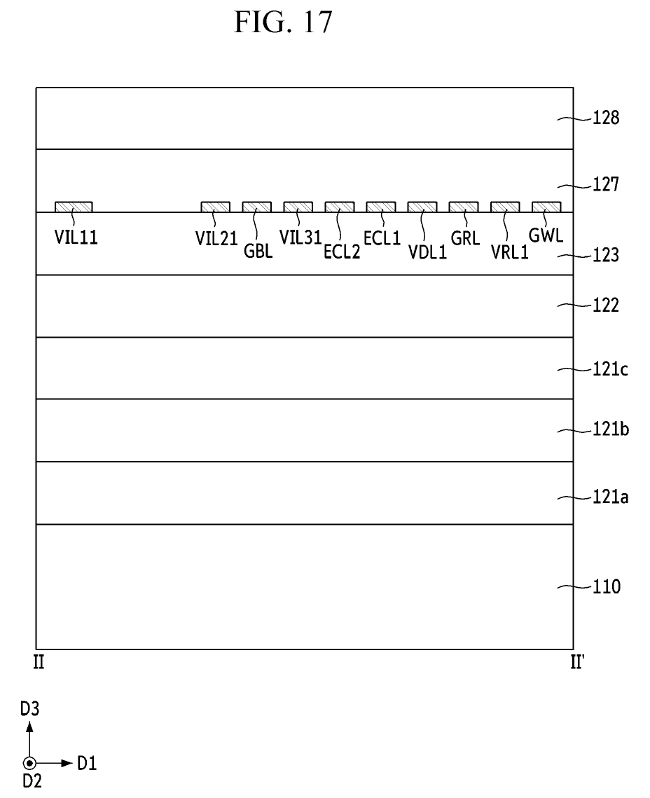

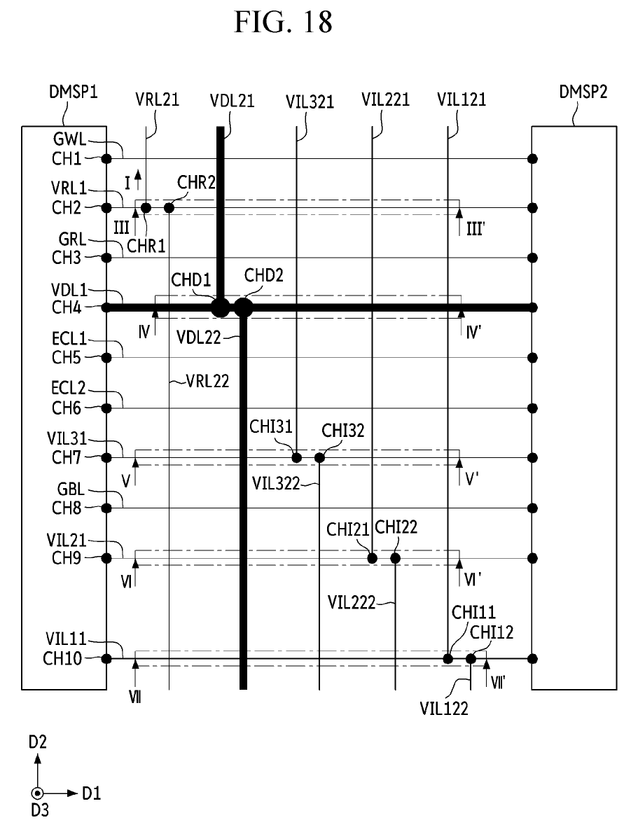

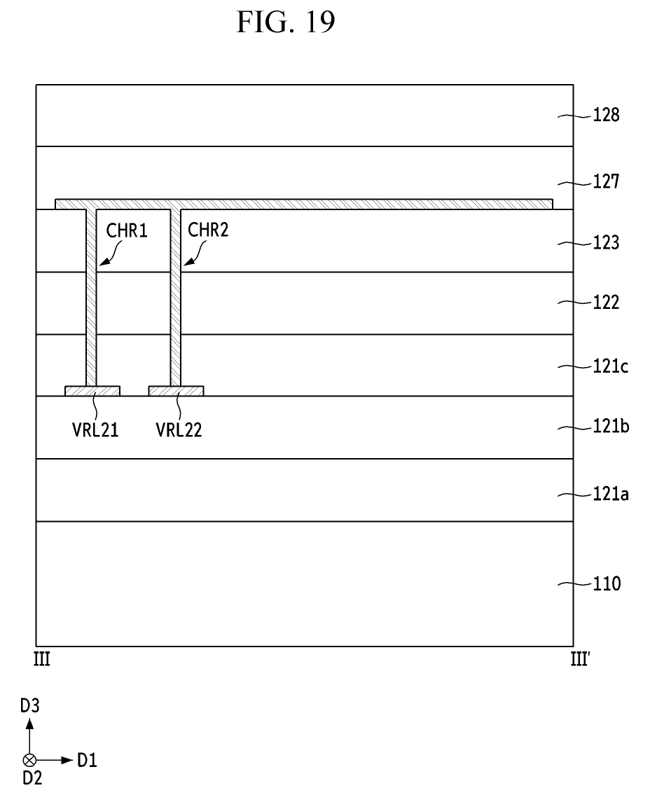

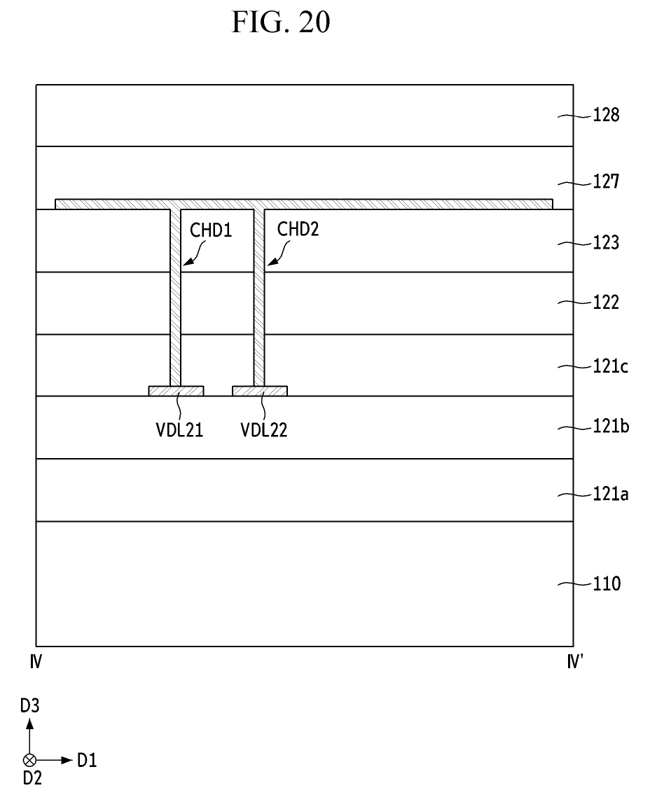

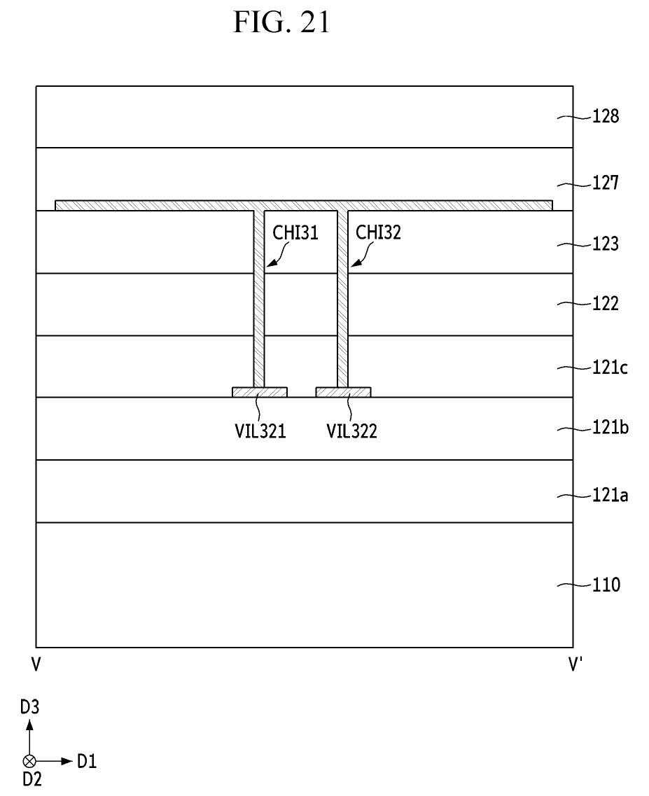

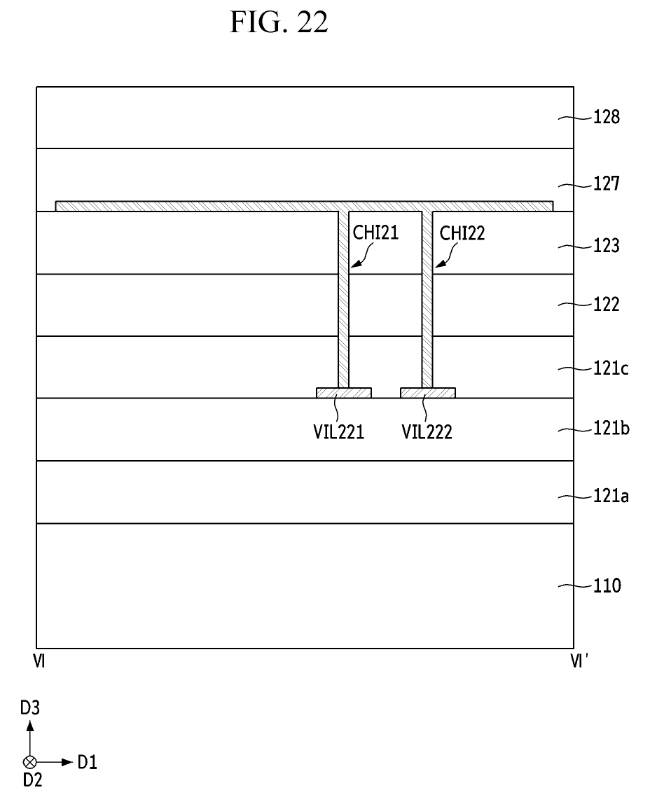

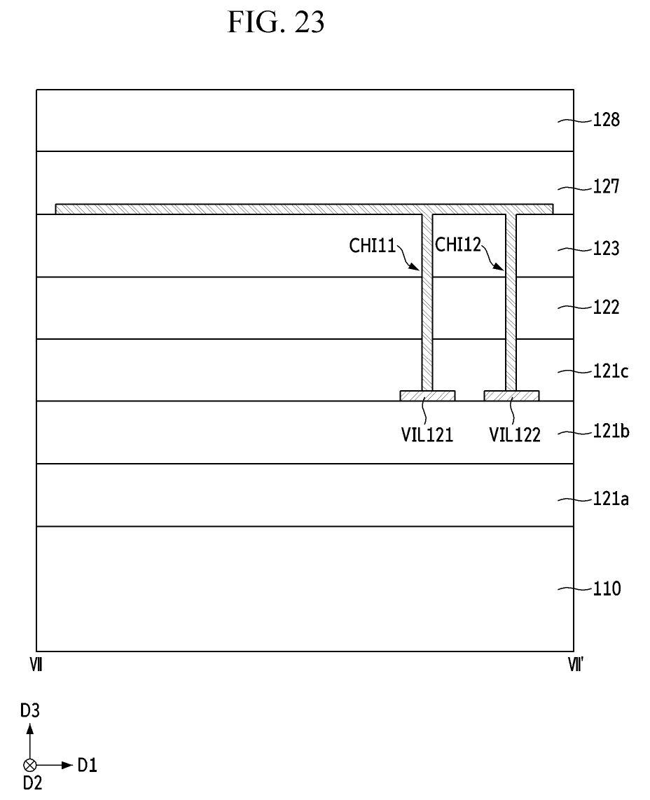

FIGS. 14, 15 and 16, are cross-sectional views taken along the line I-I’ of FIG. 12. FIG. 17 is a cross-sectional view taken along the line II-II’ of FIG. 12. FIG. 18 is a plan view illustrating cut areas of FIGS. 19-23. FIG. 19 is a cross-sectional view taken along the line III-III’ of FIG. 18. FIG. 20 is a cross-sectional view taken along the line IV-IV’ of FIG. 18. FIG. 21 is a cross-sectional view taken along the line V-V’ of FIG. 18. FIG. 22 is a cross-sectional view taken along the line VI-VI’ of FIG. 18. FIG. 23 is a cross-sectional view taken along the line VII-VII’ of FIG. 18.

Referring to FIGS. 14-16, a plurality of constant voltage lines included in the second constant voltage line group may all be formed in (e.g., at) the same layer. For example, the constant voltage lines may all be included in the first bottom metal layer BML1, included in the second bottom metal layer BML2, or included in the gate metal layer GAT.

Referring to FIG. 17, a plurality of constant voltage lines included in the first constant voltage line group may all be formed in (e.g., at) the same layer. For example, the constant voltage lines may all be included in the first bottom metal layer BML1, included in the second bottom metal layer BML2, or included in the gate metal layer GAT.

Referring to FIGS. 14-16 and FIG. 17, the first constant voltage line group may include a constant voltage line located in a different layer from any one constant voltage line included in the second constant voltage line group.

The reference voltage line VRL1 of the first constant voltage line group may be located in a different layer from the reference voltage line VRL2 of the second constant voltage line group. The first driving voltage line VDL1 of the first constant voltage line group may be located in a different layer from the first driving voltage line VDL2 of the second constant voltage line group. The first initialization voltage line VIL11 of the first constant voltage line group may be located in a different layer from the first initialization voltage line VIL12 of the second constant voltage line group. The second initialization voltage line VIL21 of the first constant voltage line group may be located in a different layer from the second initialization voltage line VIL22 of the second constant voltage line group. The third initialization voltage line VIL31 of the first constant voltage line group may be located in a different layer from the third initialization voltage line VIL32 of the second constant voltage line group.

Lines extending in the first direction D1 may further include a scan line group and an emission control line group, in addition to the first constant voltage line group. Both the scan line group and the emission control line group may be formed in (e.g., at) the same layer as the first constant voltage line group.

Because the lines extending in the first direction D1 further include the scan line group and the emission control line group, unlike the second constant voltage line group having a relatively small number of the second constant voltage line group, the second constant voltage line group may be placed below the first constant voltage line group for ease of line design.

For example, referring to FIGS. 14 and 17, the first constant voltage line group may be included in the first connection metal layer SD1, and the second constant voltage line group may be included in the first bottom metal layer BML1.

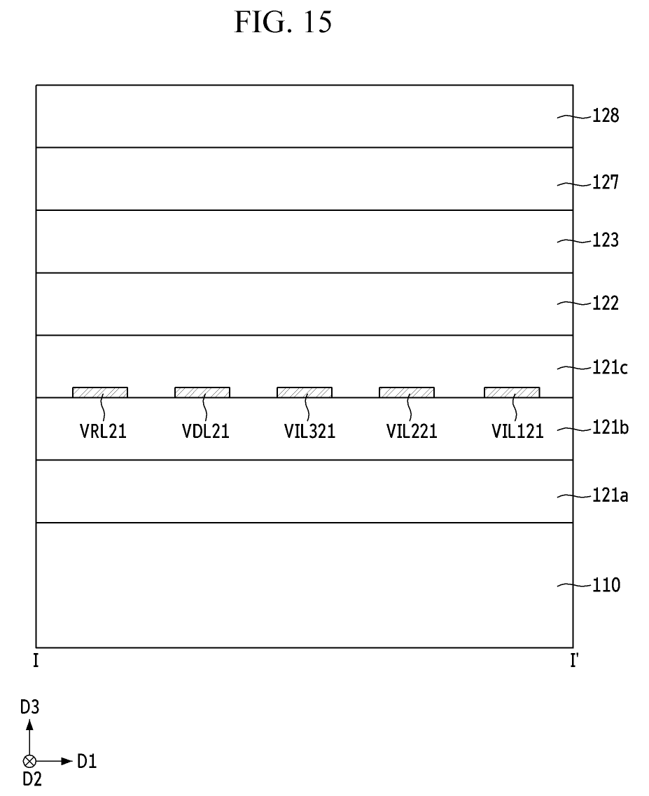

For example, referring to FIGS. 15 and 17, the first constant voltage line group may be included in the first connection metal layer SD1, and the second constant voltage line group may be included in the second bottom metal layer BML2.

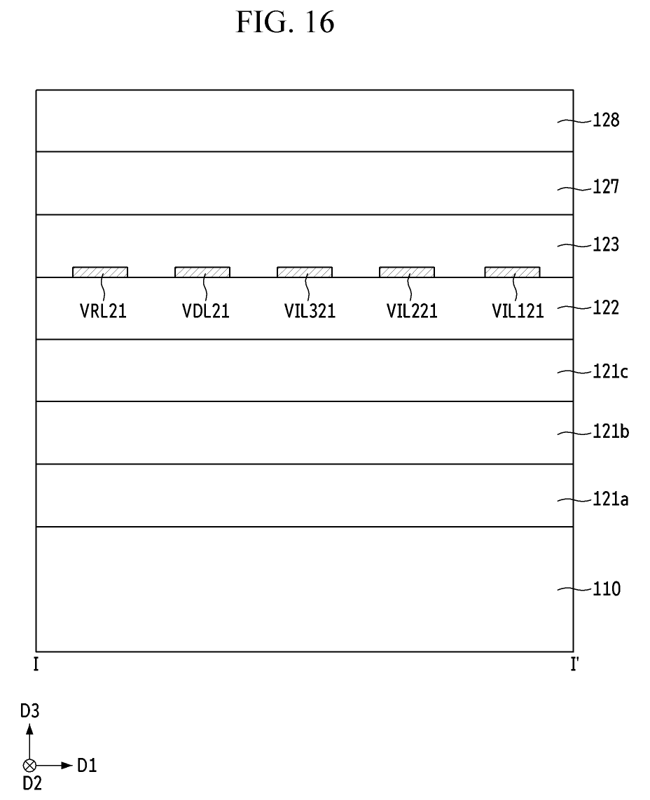

For example, referring to FIGS. 16 and 17, the first constant voltage line group may be included in the first connection metal layer SD1, and the second constant voltage line group may be included in the gate metal layer GAT.

However, the present disclosure is not limited to the above examples. When the first constant voltage line group is located in (e.g., at) the same layer as the scan line group and the emission control line group, the second constant voltage line group may be formed in a different layer from the first constant voltage line group in the display device according to one or more embodiments of the present disclosure. Accordingly, a line design area and a contact hole design area can be additionally secured.

In one or more embodiments, the first constant voltage line group may be included in the first bottom metal layer BML1, and the second constant voltage line group may be included in the second bottom metal layer BML2.

The first constant voltage line group may be included in the first bottom metal layer BML1, and the second constant voltage line group may be included in the gate metal layer GAT.

The first constant voltage line group may be included in the first bottom metal layer BML1, and the second constant voltage line group may be included in the first connection metal layer SD1.

In one or more embodiments, the first constant voltage line group may be included in the second bottom metal layer BML2, and the second constant voltage line group may be included in the first bottom metal layer BML1.

The first constant voltage line group may be included in the second bottom metal layer BML2, and the second constant voltage line group may be included in the gate metal layer GAT.

The first constant voltage line group may be included in the second bottom metal layer BML2, and the second constant voltage line group may be included in the first connection metal layer SD1.

In one or more embodiments, the first constant voltage line group may be included in the gate metal layer GAT, and the second constant voltage line group may be included in the first bottom metal layer BML1.

The first constant voltage line group may be included in the gate metal layer GAT, and the second constant voltage line group may be included in the second bottom metal layer BML2.

The first constant voltage line group may be included in the gate metal layer GAT, and the second constant voltage line group may be included in the first connection metal layer SD1.

In this way, all combinations and modifications of embodiments are possible within the range in which the contact hole area and the line design area can be secured between a first dummy subpixel DMSP1 and a second dummy subpixel DMSP2.

FIGS. 18 and 19, and 20, and 21, and 22, and 23, disclose cross-sectional views of an embodiment in which the first constant voltage line group is included in the first connection metal layer SD1, and the second constant voltage line group is included in the second bottom metal layer BML2.

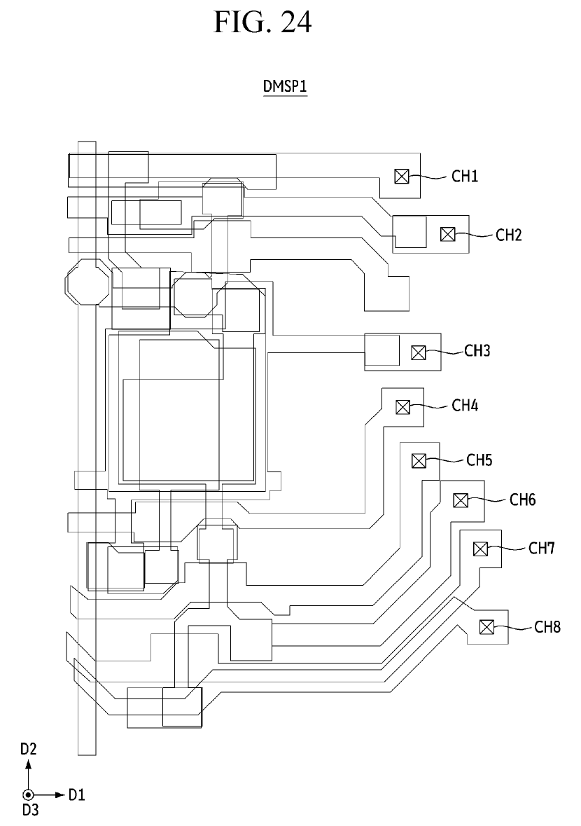

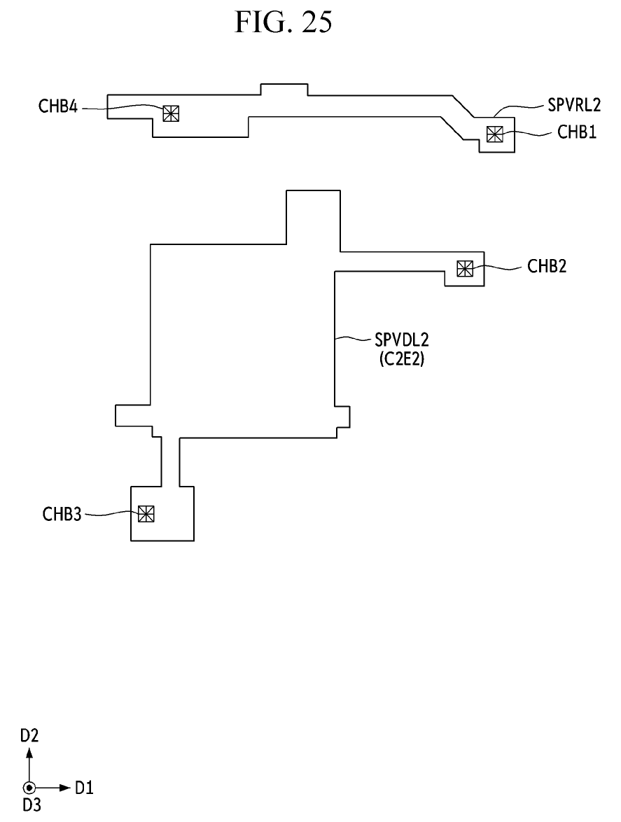

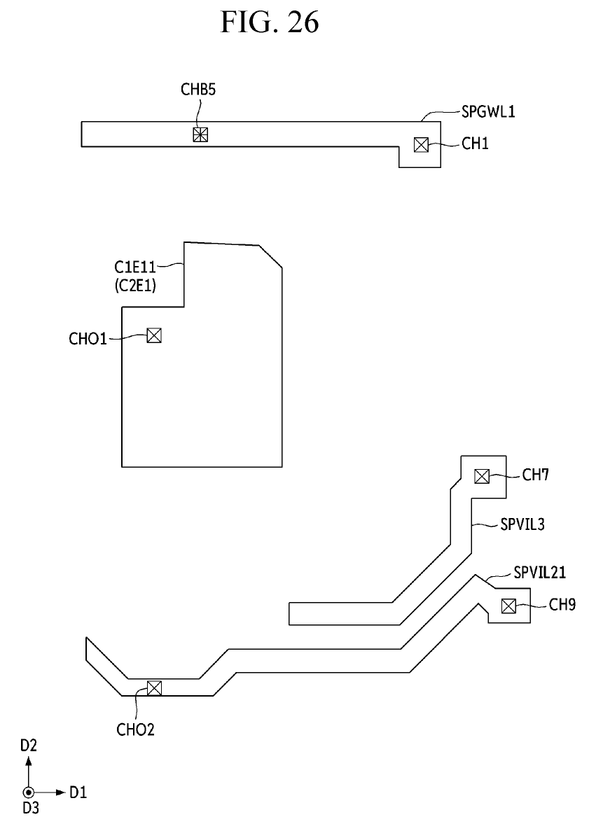

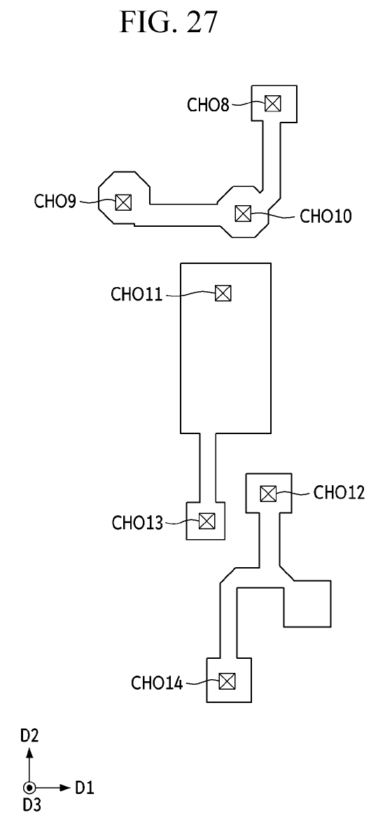

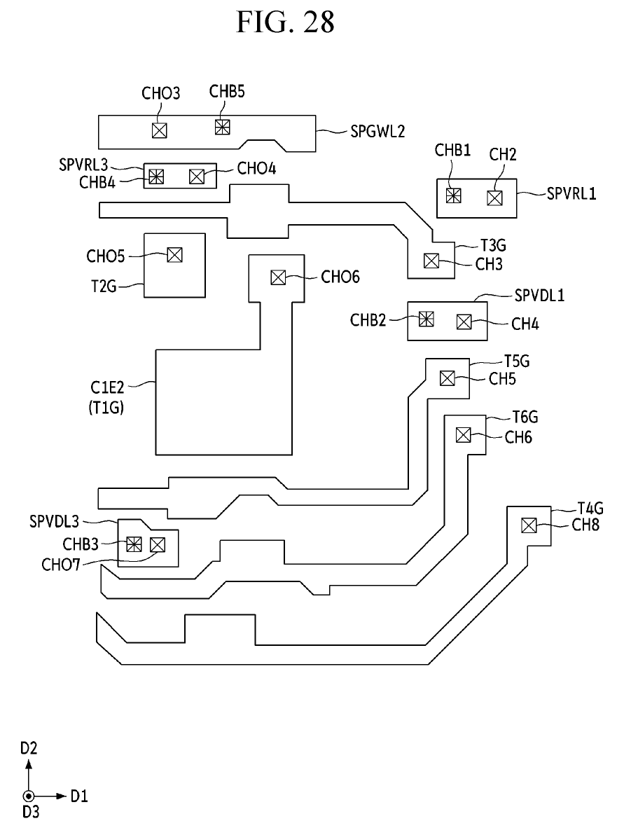

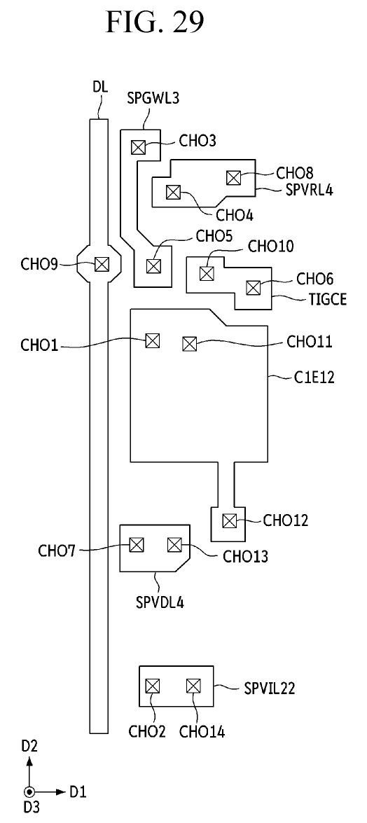

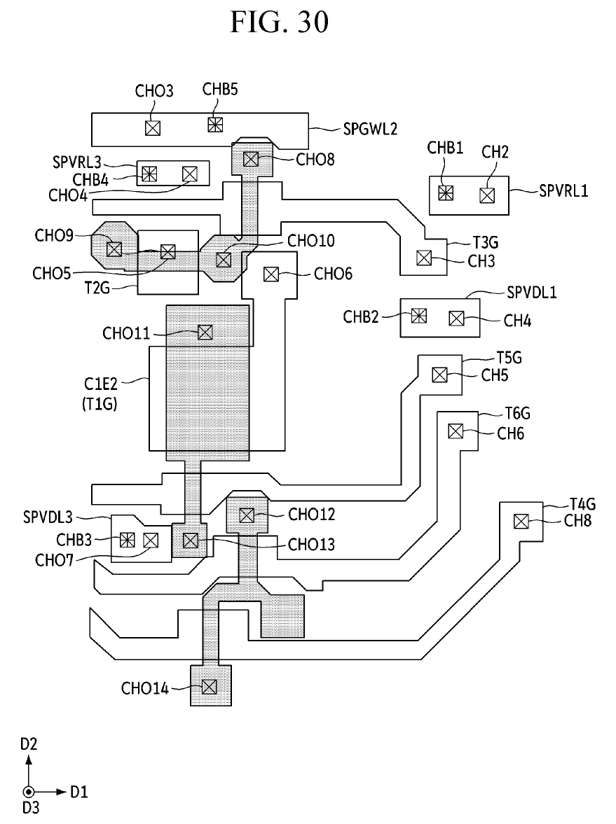

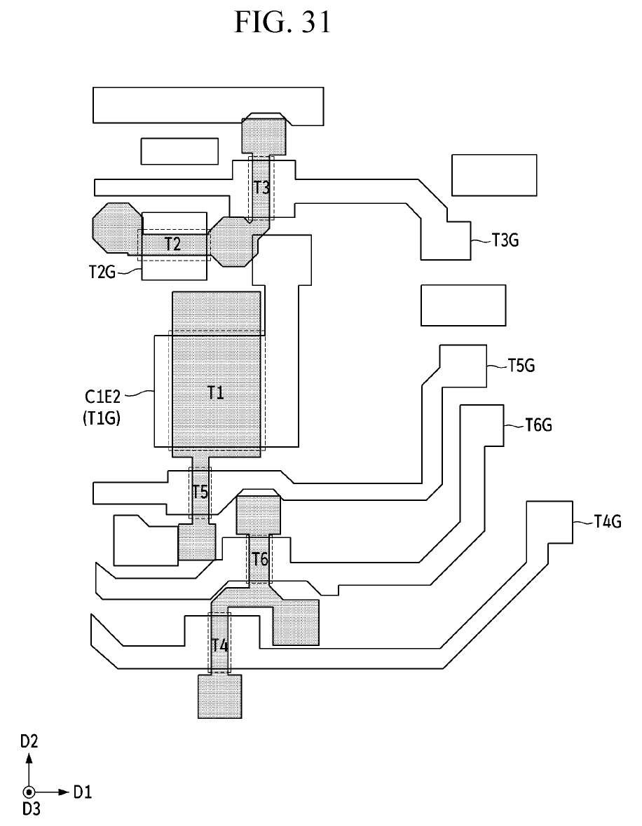

FIG. 24 is a plan view of a first dummy subpixel DMSP1 according to one or more embodiments of the present disclosure. FIG. 25 is a plan view of a first bottom metal layer according to one or more embodiments of the present disclosure. FIG. 26 is a plan view of a second bottom metal layer according to one or more embodiments of the present disclosure. FIG. 27 is a plan view of an active layer according to one or more embodiments of the present disclosure. FIG. 28 is a plan view of a gate metal layer according to one or more embodiments of the present disclosure. FIG. 29 is a plan view of a connection metal layer according to one or more embodiments of the present disclosure. FIGS. 30 and 31 are plan views of the active layer and the gate metal layer according to one or more embodiments of the present disclosure.

The first dummy subpixel DMSP1 may have substantially the same structure as a second dummy subpixel DMSP2. A subpixel SP located in the display area DA may also have substantially the same structure as the first dummy subpixel DMSP1 or the second dummy subpixel DMSP2.

However, the first dummy subpixel DMSP1 may include an electrode or line not electrically connected to transistors. The electrode or line not electrically connected to transistors in the first dummy subpixel DMSP1 may be electrically connected to transistors in the subpixel SP located in the display area DA.

For example, as illustrated (e.g., in FIGS. 24-31), a third initialization voltage line SPVIL3 in a pixel circuit does not have any electrical connection relationship with an electrode of a fourth transistor T4.

In the subpixel SP located in the display area DA, the third initialization voltage line SPVIL3 in the pixel circuit may be electrically connected to the electrode of the fourth transistor T4 through a separate line or electrode.

In the first dummy subpixel DMSP1, because a light emitting element is not placed in principle, an electrode or line not electrically connected to transistors may be placed. However, the present disclosure is not limited to this case.

For example, in principle, a first sub-electrode or line SPVIL21 of a second initialization voltage line in the pixel circuit may not have any electrical connection relationship with the electrode of the fourth transistor T4. However, the present disclosure is not limited to this example. Therefore, as illustrated (e.g., in FIGS. 24-31), the first sub-electrode or line SPVIL21 of the second initialization voltage line in the pixel circuit may also be electrically connected to the fourth transistor T4 through a seventeenth contact hole CHO2 and a twenty-ninth contact hole CHO14.

Therefore, the first dummy subpixel DMSP1 may be distinguished from the subpixel SP located in the display area DA based on whether a light emitting element is placed.

The scan line group, the emission control line group, and the first constant voltage line group may be electrically connected to the first dummy subpixel DMSP1 through a first contact hole CH1, a second contact hole CH2, a third contact hole CH3, a fourth contact hole CH4, a fifth contact hole CH5, a sixth contact hole CH6, a seventh contact hole CH7, an eighth contact hole CH8, a ninth contact hole CH9, and a tenth contact hole CH10 (e.g., see FIG. 11).

Referring to FIG. 24 (and FIG. 26), in the first dummy subpixel DMSP1 according one or more embodiments of the present disclosure, only the first contact hole CH1, the second contact hole CH2, the third contact hole CH3, the fourth contact hole CH4, the fifth contact hole CH5, the sixth contact hole CH6, the seventh contact hole CH7, the eighth contact hole CH8, and the ninth contact hole CH9 (e.g., see FIG. 26) are illustrated.

An electrode or line that transmits a first initialization voltage supplied through the tenth contact hole CH10 is not illustrated.

In addition, the illustrated first dummy subpixel DMSP1 may include the first contact hole CH1, the second contact hole CH2, the third contact hole CH3, the fourth contact hole CH4, the fifth contact hole CH5, the sixth contact hole CH6, the seventh contact hole CH7, the eighth contact hole CH8, the ninth contact hole CH9, an eleventh contact hole CHB1, a twelfth contact hole CHB2, a thirteenth contact hole CHB3, a fourteenth contact hole CHB4, a fifteenth contact hole CHB5, a sixteenth contact hole CHO1, the seventeenth contact hole CHO2, an eighteenth contact hole CHO3, a nineteenth contact hole CHO4, a twentieth contact hole CHO5, a twenty-first contact hole CHO6, a twenty-second contact hole CHO7, a twenty-third contact hole CHO8, a twenty-fourth contact hole CHO9, a twenty-fifth contact hole CHO10, a twenty-sixth contact hole CHO11, a twenty-seventh contact hole CHO12, a twenty-eighth contact hole CHO13, and the twenty-ninth contact hole CHO14.

A first sub-electrode or line SPGWL1 of a scan write line in the pixel circuit, the third initialization voltage line SPVIL3 in the pixel circuit, and the first sub-electrode or line SPVIL21 of the second initialization voltage line in the pixel circuit included in the second bottom metal layer BML2 may be electrically connected to the scan line group or the first constant voltage line group through the first contact hole CH1, the seventh contact hole CH7, and the ninth contact hole CH9, respectively.

A first sub-electrode or line SPVRL1 of a reference voltage line in the pixel circuit, a gate electrode T3G of a third transistor T3, a first sub-electrode or line SPVDL1 of a first driving voltage line in the pixel circuit, a gate electrode T5G of a fifth transistor T5, a gate electrode T6G of a sixth transistor T6, and a gate electrode T4G of the fourth transistor T4 included in the gate metal layer GAT may be electrically connected to the scan line group, the emission control line group, and the first constant voltage line group through the second contact hole CH2, the third contact hole CH3, the fourth contact hole CH4, the fifth contact hole CH5, the sixth contact hole CH6, and the eighth contact hole CH8, respectively.

Referring to FIG. 29, a data signal may be supplied to a data line DL.

Referring to FIGS. 27, 30 and 31, an electrode of a second transistor T2 may be electrically connected to the data line DL through the twenty-fourth contact hole CHO9. The electrode of the second transistor T2 may receive the data signal from the data line DL.

Referring to FIGS. 18 and 26, the first sub-electrode or line SPGWL1 of the scan write line in the pixel circuit may be electrically connected to a write scan line GWL through the first contact hole CH1. The first sub-electrode or line SPGWL1 of the scan write line in the pixel circuit may receive a write scan signal from the write scan line GWL.

Referring to FIG. 28, a second sub-electrode or line SPGWL2 of the scan write line in the pixel circuit may be electrically connected to the first sub-electrode or line SPGWL1 of the scan write line in the pixel circuit through the fifteenth contact hole CHB5. The second sub-electrode or line SPGWL2 of the scan write line in the pixel circuit may receive the write scan signal from the first sub-electrode or line SPGWL1 of the scan write line in the pixel circuit.

Referring to FIG. 29, a third sub-electrode or line SPGWL3of the scan write line in the pixel circuit may be electrically connected to the second sub-electrode or line SPGWL2 of the scan write line in the pixel circuit through the eighteenth contact hole CHO3. The third sub-electrode or line SPGWL3 of the scan write line in the pixel circuit may receive the write scan signal from the second sub-electrode or line SPGWL2 of the scan write line in the pixel circuit.

Referring to FIG. 28, a gate electrode T2G of the second transistor T2 may be electrically connected to the third sub-electrode or line SPGWL3 of the scan write line in the pixel circuit through the twentieth contact hole CHO5. The gate electrode T2G of the second transistor T2 may receive the write scan signal from the third sub-electrode or line SPGWL3 of the scan write line in the pixel circuit.

Referring to FIG. 31, the second transistor T2 may include the gate electrode T2G of the second transistor T2. The second transistor T2 may be turned on or off according to the write scan signal applied to the gate electrode T2G of the second transistor T2.

When the second transistor T2 is turned on, the second transistor T2 may transmit a received data signal to another electrode of the second transistor T2.

Referring to FIGS. 18 and 26, the third initialization voltage line SPVIL3 in the pixel circuit may be electrically connected to a third initialization voltage line VIL31 of the first constant voltage line group through the seventh contact hole CH7. The third initialization voltage line SPVIL3 in the pixel circuit may receive a third initialization voltage from the third initialization voltage line VIL31 of the first constant voltage line group.

Referring to FIGS. 18 and 26, the first sub-electrode or line SPVIL21 of the second initialization voltage line in the pixel circuit may be electrically connected to a second initialization voltage line VIL21 of the first constant voltage line group through the ninth contact hole CH9. The first sub-electrode or line SPVIL21 of the second initialization voltage line in the pixel circuit may receive a second initialization voltage from the second initialization voltage line VIL21 of the first constant voltage line group.

Referring to FIG. 29, a second sub-electrode or line SPVIL22 of the second initialization voltage line in the pixel circuit may be electrically connected to the first sub-electrode or line SPVIL21 of the second initialization voltage line in the pixel circuit through the seventeenth contact hole CHO2. The second sub-electrode or line SPVIL22 of the second initialization voltage line in the pixel circuit may receive the second initialization voltage from the first sub-electrode or line SPVIL21 of the second initialization voltage line in the pixel circuit.

Referring to FIGS. 27, 30, and 31, an electrode of the fourth transistor T4 may be electrically connected to the second sub-electrode or line SPVIL22 of the second initialization voltage line in the pixel circuit through the twenty-ninth contact hole CHO14. The electrode of the fourth transistor T4 may receive the second initialization voltage from the second sub-electrode or line SPVIL22 of the second initialization voltage line in the pixel circuit.

Not limited to the supply of second initialization voltage illustrated herein.

As described above, the first initialization voltage may be supplied to a first subpixel, the second initialization voltage may be supplied to a second subpixel, and the third initialization voltage may be supplied to a third subpixel. The first initialization voltage, the second initialization voltage, and the third initialization voltage are all initialization voltages. However, the first initialization voltage, the second initialization voltage, and the third initialization voltage are distinguished from each other because they are all supplied by different lines.

If the first dummy subpixel DMSP1 corresponds to the first subpixel, the first initialization voltage will be supplied to the first dummy subpixel DMSP1.

If the first dummy subpixel DMSP1 corresponds to the second subpixel, the second initialization voltage will be supplied to the first dummy subpixel DMSP1.

If the first dummy subpixel DMSP1 corresponds to the third subpixel, the third initialization voltage will be supplied to the first dummy subpixel DMSP1.

A light emitting element is not placed in the first dummy subpixel DMSP1. Because the first dummy subpixel DMSP1 cannot emit light, it is not possible to know which of the first subpixel, the second subpixel, and the third subpixel, the first dummy subpixel DMSP1 corresponds to.

In relation to the second initialization voltage and the third initialization voltage described above, the second initialization voltage is illustrated as being supplied to the electrode of the fourth transistor T4. A line that transmits the first initialization voltage is omitted in the present disclosure.

Although the second initialization voltage is illustrated as being supplied to the electrode of the fourth transistor T4, the present disclosure is not limited to this case. One of the first initialization voltage, the second initialization voltage, and the third initialization voltage may be supplied to the electrode of the fourth transistor T4.

Referring to FIGS. 18 and 28, the first sub-electrode or line SPVRL1 of the reference voltage line in the pixel circuit may be electrically connected to a reference voltage line VRL1 of the first constant voltage line group through the second contact hole CH2. The first sub-electrode or line SPVRL1 of the reference voltage line in the pixel circuit may receive a reference voltage from the reference voltage line VRL1 of the first constant voltage line group.

Referring to FIG. 25, a second sub-electrode or line SPVRL2 of the reference voltage line in the pixel circuit may be electrically connected to the first sub-electrode or line SPVRL1 of the reference voltage line in the pixel circuit through the eleventh contact hole CHB1. The second sub-electrode or line SPVRL2 of the reference voltage line in the pixel circuit may receive the reference voltage from the first sub-electrode or line SPVRL1 of the reference voltage line in the pixel circuit.

Referring to FIG. 28, a third sub-electrode or line SPVRL3 of the reference voltage line in the pixel circuit may be electrically connected to the second sub-electrode or line SPVRL2 of the reference voltage line in the pixel circuit through the fourteenth contact hole CHB4. The third sub-electrode or line SPVRL3 of the reference voltage line in the pixel circuit may receive the reference voltage from the second sub-electrode or line SPVRL2 of the reference voltage line in the pixel circuit.

Referring to FIG. 29, a fourth sub-electrode or line SPVRL4 of the reference voltage line in the pixel circuit may be electrically connected to the third sub-electrode or line SPVRL3 of the reference voltage line in the pixel circuit through the nineteenth contact hole CHO4. The fourth sub-electrode or line SPVRL4 of the reference voltage line in the pixel circuit may receive the reference voltage from the third sub-electrode or line SPVRL3 of the reference voltage line in the pixel circuit.

Referring to FIGS. 27, 30, and 31, an electrode of the third transistor T3 may be electrically connected to the fourth sub-electrode or line SPVRL4 of the reference voltage line in the pixel circuit through the twenty-third contact hole CHO8. The electrode of the third transistor T3 may receive the reference voltage from the fourth sub-electrode or line SPVRL4 of the reference voltage line in the pixel circuit.

Referring to FIGS. 18 and 28, the gate electrode T3G of the third transistor T3 may be electrically connected to a reset control line GRL through the third contact hole CH3. The gate electrode T3G of the third transistor T3 may receive a reset control signal from the reset control line GRL.

Referring to FIG. 31, the third transistor T3 may include the gate electrode T3G of the third transistor T3. The third transistor T3 may be turned on or off according to the reset control signal applied to the gate electrode T3G of the third transistor T3.

When the third transistor T3 is turned on, the third transistor T3 may transmit a received reference voltage to another electrode of the third transistor T3.

Referring to FIGS. 18 and 28, the first sub-electrode or line SPVDL1 of the first driving voltage line in the pixel circuit may be electrically connected to a first driving voltage line VDL1 of the first constant voltage line group through the fourth contact hole CH4. The first sub-electrode or line SPVDL1 of the first driving voltage line in the pixel circuit may receive a first driving voltage from the first driving voltage line VDL1 of the first constant voltage line group.

Referring to FIG. 25, a second sub-electrode or line SPVDL2 of the first driving voltage line in the pixel circuit may be electrically connected to the first sub-electrode or line SPVDL1 of the first driving voltage line in the pixel circuit through the twelfth contact hole CHB2. The second sub-electrode or line SPVDL2 of the first driving voltage line in the pixel circuit may receive the first driving voltage from the first sub-electrode or line SPVDL1 of the first driving voltage line in the pixel circuit.

Referring to FIG. 28, a third sub-electrode or line SPVDL3 of the first driving voltage line in the pixel circuit may be electrically connected to the second sub-electrode or line SPVDL2 of the first driving voltage line in the pixel circuit through the thirteenth contact hole CHB3. The third sub-electrode or line SPVDL3 of the first driving voltage line in the pixel circuit may receive the first driving voltage from the second sub-electrode or line SPVDL2 of the first driving voltage line in the pixel circuit.

Referring to FIG. 29, a fourth sub-electrode or line SPVDL4 of the first driving voltage line in the pixel circuit may be electrically connected to the third sub-electrode or line SPVDL3 of the first driving voltage line in the pixel circuit through the twenty-second contact hole CHO7. The fourth sub-electrode or line SPVDL4 of the first driving voltage line in the pixel circuit may receive the first driving voltage from the third sub-electrode or line SPVDL3 of the first driving voltage line in the pixel circuit.

Referring to FIGS. 27, 30, and 31, an electrode of the fifth transistor T5 may be electrically connected to the fourth sub-electrode or line SPVDL4 of the first driving voltage line in the pixel circuit through the twenty-eighth contact hole CHO13. The electrode of the fifth transistor T5 may receive the first driving voltage from the fourth sub-electrode or line SPVDL4 of the first driving voltage line in the pixel circuit.

Referring to FIGS. 18 and 28, the gate electrode T5G of the fifth transistor T5 may be electrically connected to a first emission control line ECL1 through the fifth contact hole CH5. The gate electrode T5G of the fifth transistor T5 may receive a first emission control signal from the first emission control line ECL1.

Referring to FIG. 31, the fifth transistor T5 may include the gate electrode T5G of the fifth transistor T5. The fifth transistor T5 may be turned on or off according to the first emission control signal applied to the gate electrode T5G of the fifth transistor T5.

When the fifth transistor T5 is turned on, the fifth transistor T5 may transmit a received first driving voltage to another electrode of the fifth transistor T5.

Referring to FIGS. 18 and 28, the gate electrode T6G of the sixth transistor T6 may be electrically connected to a second emission control line ECL2 through the sixth contact hole CH6. The gate electrode T6G of the sixth transistor T6 may receive a second emission control signal from the second emission control line ECL2.

Referring to FIG. 31, the sixth transistor T6 may include the gate electrode T6G of the sixth transistor T6. The sixth transistor T6 may be turned on or off according to the second emission control signal applied to the gate electrode T6G of the sixth transistor T6.

When the sixth transistor T6 is turned on, the sixth transistor T6 may transmit a received driving current or initialization voltage to another electrode of the sixth transistor T6.

Referring to FIGS. 18 and 28, the gate electrode T4G of the fourth transistor T4 may be electrically connected to a bias scan line GBL through the eighth contact hole CH8. The gate electrode T4G of the fourth transistor T4 may receive a bias scan signal from the bias scan line GBL.

Referring to FIG. 31, the fourth transistor T4 may include the gate electrode T4G of the fourth transistor T4. The fourth transistor T4 may be turned on or off according to the bias scan signal applied to the gate electrode T4G of the fourth transistor T4.

When the fourth transistor T4 is turned on, the fourth transistor T4 may transmit a received initialization voltage to another electrode of the fourth transistor T4.

A first transistor T1 may include a gate electrode T1G of the first transistor T1, which is electrically connected to an electrode of the second transistor T2 and an electrode of the third transistor T3. The gate electrode T1G of the first transistor T1 may function as a second electrode C1E2 of a first capacitor C1 (e.g., FIG. 7).

An electrode of the first transistor T1 may be electrically connected to an electrode of the fifth transistor T5, and another electrode of the first transistor T1 may be electrically connected to an electrode of the sixth transistor T6. The another electrode of the first transistor T1 may be electrically connected to the electrode of the sixth transistor T6 through the twenty-seventh contact hole CHO12.

Referring to FIGS. 27, 29, 30, and 31, the connection electrode T1GCE of the gate electrode T1G of the first transistor T1 may be electrically connected to the electrode of the second transistor T2 and the electrode of the third transistor T3 through the twenty-fifth contact hole CHO10.

Referring to FIG. 28, the gate electrode T1G of the first transistor T1 may be electrically connected to the connection electrode T1GCE of the gate electrode T1G of the first transistor T1 through the twenty-first contact hole CHO6.

As described above, the gate electrode T1G of the first transistor T1 may also be the second electrode C1E2 of the first capacitor C1 (e.g., FIG. 7).

Referring to FIGS. 27, 30 and 31, the electrode of the first transistor T1 may be electrically connected (or physically connected in one layer) to the electrode of the fifth transistor T5.

Referring to FIG. 29, a first electrode C1E12 of any one first capacitor may be connected to the another electrode of the first transistor T1 through the twenty-sixth contact hole CHO11.

Referring to FIG. 26, a first electrode C1E11 of another first capacitor may be connected to the first electrode C1E12 of the any one first capacitor through the sixteenth contact hole CHO1.

The first electrode C1E12 of the any one first capacitor may have the same potential as the first electrode C1E11 of the another first capacitor C1(e.g., FIG. 7).

The gate electrode T1G of the first transistor T1 may also be the second electrode C1E2 of the first capacitor C1 (e.g., FIG. 7).

Therefore, the gate electrode T1G of the first transistor T1 may form any one first capacitor with the first electrode C1E12 of the any one first capacitor and may form another first capacitor with the first electrode C1E11 of the another first capacitor. They may overlap each other in the third direction D3.

For example, a first capacitor may include any one first capacitor and another first capacitor. The any one first capacitor and the another first capacitor may share the gate electrode T1G of the first transistor T1 and may be connected in parallel to each other.

Referring to FIG. 25, the second sub-electrode or line SPVDL2 of the first driving voltage line in the pixel circuit may also be a second electrode C2E2 of a second capacitor.

As described above, the second sub-electrode or line SPVDL2 of the first driving voltage line in the pixel circuit may receive the first driving voltage from the first sub-electrode or line SPVDL1 of the first driving voltage line in the pixel circuit.

Therefore, the first driving voltage may be applied to the second electrode C2E2 of the second capacitor.

Referring to FIG. 26, the first electrode C1E11 of the another first capacitor may also be a first electrode C2E1 of the second capacitor.

As described above, the first electrode C1E11 of the another first capacitor may be connected to the first electrode C1E12 of the any one first capacitor through the sixteenth contact hole CHO1.

Therefore, the second sub-electrode or line SPVDL2 of the first driving voltage line in the pixel circuit and the first electrode C1E11 of the another first capacitor may form the second capacitor. They may overlap each other in the third direction D3.

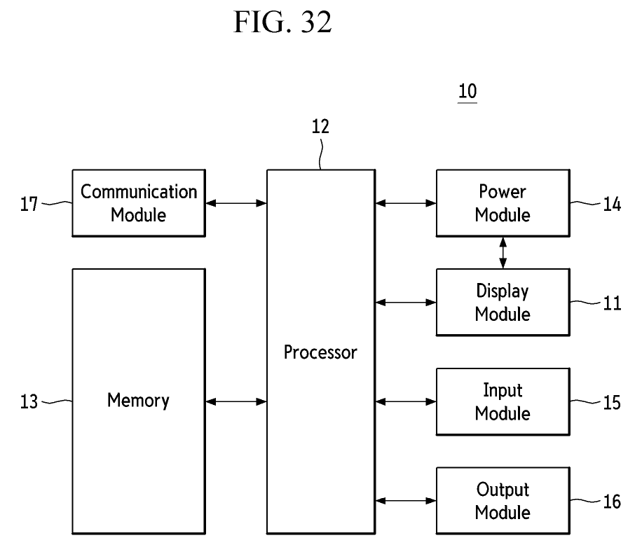

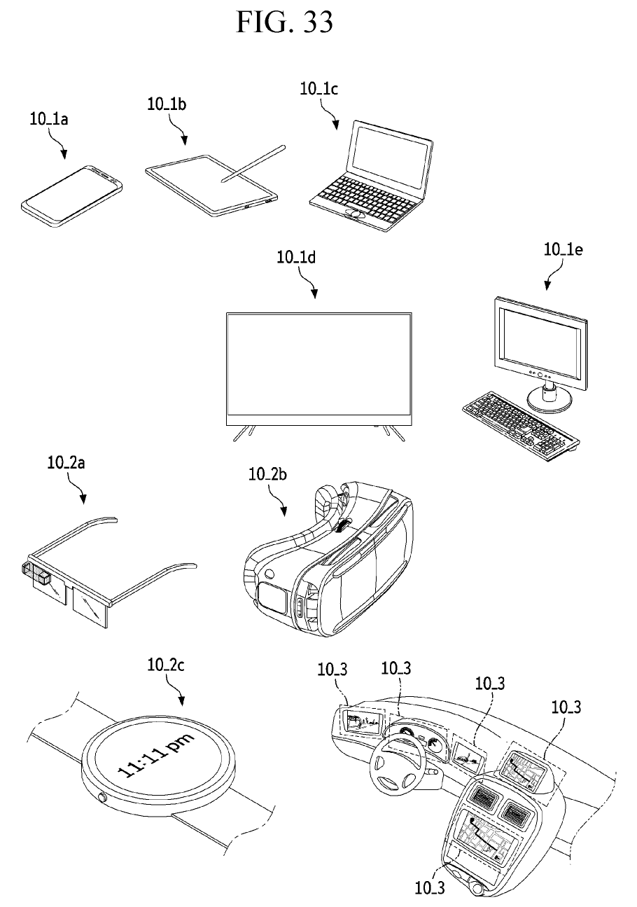

FIG. 32 is a block diagram of an electronic device according to one or more embodiments of the present disclosure. FIG. 33 is a schematic diagram of electronic devices according to various embodiments of the present disclosure.

Referring to FIG. 32, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power necessary for the operation of the electronic device 10 by converting power supplied by the power supply module.

At least one of the elements of the electronic device 10 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 10.

Referring to FIG. 33, various electronic devices to which a display device according to one or more embodiments of the present disclosure is applied may include image display electronic devices such as a smartphone 10_1a, a tablet PC 10_1b, a laptop 10_1c, a television 10_1d, and a desk monitor 10_1e. In addition, the various electronic devices to which the display device according to the embodiments of the present disclosure is applied may include wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument cluster, center fascia and dashboard of a vehicle.

Although embodiments of the present disclosure have been described above with reference to the accompanying drawings, it will be understood by those having ordinary skill in the technical field to which the present disclosure belongs that the present disclosure may be practiced in other specific forms without altering the technical idea or essential features of the present disclosure. It should therefore be understood that the embodiments described above are examples in all respects and are not intended to be limiting.

What is claimed is:

1. A display device comprising:
a display area comprising a plurality of subpixels; and
a non-display area comprising a gate driving circuit configured to output a gate signal to the subpixels, and a plurality of dummy subpixels,
wherein the dummy subpixels comprise a first dummy subpixel located between the gate driving circuit and a subpixel of the subpixels and a second dummy subpixel located between the first dummy subpixel and the subpixel, and the non-display area further comprises a scan line group, an emission control line group, and a first constant voltage line group electrically connecting the first dummy subpixel and the second dummy subpixel and extending in a first direction and a second constant voltage line group located between the first dummy subpixel and the second dummy subpixel and extending in a second direction intersecting the first direction.

2. The display device of claim 1, wherein the first constant voltage line group is electrically connected to the second constant voltage line group through a plurality of contact holes.

3. The display device of claim 1, wherein the subpixel comprises a first transistor to applying a driving current to a light emitting element, a second transistor comprising a gate electrode to which a write scan signal is applied, a third transistor comprising a gate electrode to which a reset control signal is applied, and a fourth transistor comprising a gate electrode to which a bias scan signal is applied, and the scan line group comprises a write scan line to supply the write scan signal, a reset control line to supply the reset control signal, and a bias scan line to supply the bias scan signal.

4. The display device of claim 1, wherein the subpixel comprises a first transistor to apply a driving current to a light emitting element, a fifth transistor comprising a gate electrode to which a first emission control signal is applied and a sixth transistor comprising a gate electrode to which a second emission control signal is applied, and the emission control line group comprises a firs emission control line to supply the first emission control signal and a second emission control line to supply the second emission control signal.

5. The display device of claim 1, wherein the subpixel comprises a first transistor to apply a driving current to a light emitting element, a third transistor comprising an electrode to which a reference voltage is applied, a fifth transistor comprising an electrode to which a first driving voltage is applied and a fourth transistor comprising an electrode to which an initialization voltage is applied, and the first constant voltage line group comprises a reference voltage line to supply the reference voltage, a first driving voltage line to supply the first driving voltage, and an initialization voltage line to supply the initialization voltage.

6. The display device of claim 5, wherein the initialization voltage line comprises a first initialization voltage line to supply a first initialization voltage, a second initialization voltage line to supply a second initialization voltage, and a third initialization voltage line to supplying a third initialization voltage, and the subpixels comprise a first subpixel to display a first color, a second subpixel to display a second color, and a third subpixel to display a third color, wherein the first initialization voltage is applied to the electrode of the fourth transistor in the first subpixel, the second initialization voltage is applied to the electrode of the fourth transistor in the second subpixel, and the third initialization voltage is applied to the electrode of the fourth transistor in the third subpixel.

7. The display device of claim 5, wherein the second constant voltage line group comprises:
a reference voltage line to supply the reference voltage;
a first driving voltage line to supply the first driving voltage; and
an initialization voltage line to supply the initialization voltage.

8. The display device of claim 7, wherein the initialization voltage line of the first constant voltage line group comprises a first initialization voltage line to supply a first initialization voltage, a second initialization voltage line to supply a second initialization voltage, and a third initialization voltage line to supply a third initialization voltage, the initialization voltage line of the second constant voltage line group comprises a first initialization voltage line to supply a first initialization voltage, a second initialization voltage line to supply a second initialization voltage and a third initialization voltage line to supply a third initialization voltage, and the subpixels comprise a first subpixel to display a first color, a second subpixel to display a second color, and a third subpixel to display a third color, wherein the first initialization voltage is applied to the electrode of the fourth transistor in the first subpixel, the second initialization voltage is applied to the electrode of the fourth transistor in the second subpixel, and the third initialization voltage is applied to the electrode of the fourth transistor in the third subpixel.

9. The display device of claim 1, wherein the second constant voltage line group is located between a plurality of contact holes electrically connecting the first dummy subpixel and the first constant voltage line group and a plurality of contact holes electrically connecting the second dummy subpixel and the first constant voltage line group.

10. The display device of claim 1, wherein the non-display area comprises a bottom metal layer, a gate metal layer located on the bottom metal layer, and a connection metal layer located on the gate metal layer, a plurality of constant voltage lines in the first constant voltage line group are located in a same layer, and a plurality of constant voltage lines in the second constant voltage line group are located in a same layer.

11. The display device of claim 1, wherein the non-display area comprises a bottom metal layer, a gate metal layer located on the bottom metal layer, and a connection metal layer located on the gate metal layer, and the first constant voltage line group comprises a constant voltage line located in a different layer from a constant voltage line in the second constant voltage line group.

12. The display device of claim 11, wherein the first constant voltage line group comprises a constant voltage line located on a constant voltage line in the second constant voltage line group.

13. The display device of claim 11, wherein the first constant voltage line group is located on the second constant voltage line group.

14. The display device of claim 8, wherein the reference voltage line of the second constant voltage line group comprises a first sub-reference voltage line and a second sub-reference voltage line which supply the reference voltage.

15. The display device of claim 14, wherein the reference voltage line of the first constant voltage line group is electrically connected to the first sub-reference voltage line and electrically connected to the second sub-reference voltage line.

16. An electronic device comprising:
a processor configured to provide an image signal;
a display module configured to receive the image signal from the processor and display an image; and
a power module configured to supply power to the display module,
wherein the display module comprises:
a display area comprising a plurality of subpixels; and
a non-display area comprising a gate driving circuit configured to output a gate signal to the subpixels, and a plurality of dummy subpixels,
wherein the dummy subpixels comprise a first dummy subpixel located between the gate driving circuit and a subpixel of the subpixels and a second dummy subpixel located between the first dummy subpixel and the subpixel, and the non-display area further comprises a scan line group, an emission control line group, and a first constant voltage line group electrically connecting the first dummy subpixel and the second dummy subpixel and extending in a first direction and a second constant voltage line group located between the first dummy subpixel and the second dummy subpixel and extending in a second direction intersecting the first direction.

17. The electronic device of claim 16, wherein the subpixel comprises a first transistor to apply a driving current to a light emitting element, a third transistor comprising an electrode to which a reference voltage is applied, a fifth transistor comprising an electrode to which a first driving voltage is applied and a fourth transistor comprising an electrode to which an initialization voltage is applied, the first constant voltage line group comprises a reference voltage line to supply the reference voltage, a first driving voltage line to supply the first driving voltage and an initialization voltage line to supply the initialization voltage, and the second constant voltage line group comprises a reference voltage line to supply the reference voltage, a first driving voltage line to supply the first driving voltage, and an initialization voltage line to supply the initialization voltage.

18. The electronic device of claim 16, wherein the second constant voltage line group is located between a plurality of contact holes electrically connecting the first dummy subpixel and the first constant voltage line group and a plurality of contact holes electrically connecting the second dummy subpixel and the first constant voltage line group.

19. The electronic device of claim 16, wherein the non-display area comprises a bottom metal layer, a gate metal layer located on the bottom metal layer, and a connection metal layer located on the gate metal layer, a plurality of constant voltage lines in the first constant voltage line group are located in a same layer, and a plurality of constant voltage lines in the second constant voltage line group are located in a same layer.

20. The electronic device of claim 16, wherein the non-display area comprises a bottom metal layer, a gate metal layer located on the bottom metal layer, and a connection metal layer located on the gate metal layer, and the first constant voltage line group comprises a constant voltage line located in a different layer from a constant voltage line in the second constant voltage line group.
